(19) United States
(12) Patent Application Publication
(10) Pub. No.: US 2015/0340636 A1
(43) Pub. Date: Nov. 26, 2015

(54) Electronic Device

(71) Applicant: MERCK PATENT GMBH, Darmstadt (DE)

(72) Inventors: Jonas Valentin Kroeber, Frankfurt Am Main (DE); Frank Voges, Bad Duerkheim (DE); Christof Pflumm, Darmstadt (DE)

(73) Assignee: Merck Patent GmbH, Darmstadt (DE)

(21) Appl. No.: 14/758,875

(22) PCT Filed: Dec. 9, 2013
(86) PCT No.: PCT/EP2013/003715

§ 371 Date: Jul. 1, 2015

(30) Foreign Application Priority Data
Jan. 3, 2013 (EP) 13000015.1

(51) Int. Cl. H01L 51/50; H01L 51/00

(52) U.S. Cl. CPC H01L 51/5004; H01L 51/0067; H01L 51/006; H01L 51/0054; H01L 51/0056; H01L 51/0069; H01L 2251/5384; H01L 2251/552; H01L 2251/562

(57) ABSTRACT

The application relates to an electronic device comprising an emitting layer which comprises at least one emitter compound and at least two host materials. The application furthermore relates to the use of the device in displays or in lighting applications.

The present application relates to an electronic device having anode, cathode and at least one emitting layer which comprises an emitter compound and two different matrix materials.

Electronic devices in the sense of this application are taken to mean so-called organic electronic devices, which comprise organic semiconductor materials as functional materials. In particular, they are taken to mean organic electroluminescent devices (OLEDs) and other electronic devices which are indicated below.

The structure of OLEDs in which organic semiconductors are employed as functional materials is described, for example, in U.S. Pat. No. 4,539,507, U.S. Pat. No. 5,151,629, EP 0676461 and WO 98/27136. In general, the term OLED is taken to mean electronic devices which comprise organic material and emit light on application of an electrical voltage.

In the case of electronic devices, in particular OLEDs, there is great interest in improving the performance data, in particular lifetime and efficiency. A completely satisfactory solution has still not been found in these aspects, in particular in the case of blue-emitting OLEDs.

In order to achieve further advances in these aspects, particular interest is directed to the composition of the emitting layer.

The prior art discloses that the efficiency of an OLED can be increased by the use of more than one single compound in the emitting layer. In the case of this technical solution, an emitter compound is employed in the emitting layer in combination with a second compound, which serves as matrix compound. The matrix compound is present in predominant proportion in the layer here. Such embodiments have been described for fluorescent emitting layers, inter alia in U.S. Pat. No. 4,769,292, U.S. Pat. No. 5,908,581, U.S. Pat. No. 5,593,788 and U.S. Pat. No. 5,141,671.

Furthermore, it is described in some publications to employ three different compounds in the emitting layer of an OLED. These three different compounds are typically an emitter compound, a first matrix compound and a second matrix compound.

An emitter compound here is taken to mean a compound which emits light during operation of the electronic device.

If a mixture of a plurality of compounds is present in the emitting layer, the emitter compound is typically the component present in smaller amount, i.e. in a smaller proportion than the other compounds present in the mixture of the emitting layer. In this case, the emitter compound is also referred to as dopant.

A matrix compound in this case is taken to mean a compound which is present in the mixture in a greater proportion than the emitter compound. The matrix compound preferably does not emit light. Even if a plurality of different matrix compounds are present in the mixture of the emitting layer, their individual proportions are typically greater than the proportion of the emitter compounds, or the proportions of the individual emitter compounds if a plurality of emitter compounds are present in the mixture of the emitting layer. Instead of the term matrix compound, the term host compound is also used synonymously.

In the prior art, EP 1227527 discloses an OLED comprising the two compounds tris-(8-hydroxyquinoline)aluminium (Alq₃) and N,N′-di-1-naphthyl-N,N′-diphenyl-1,1′-biphenyl-4,4′-diamine (NPB) as host materials and rubrene as emitter compound.

Furthermore, U.S. Pat. No. 7,504,163 discloses an OLED comprising an anthracene derivative (2-tert-butyl-9,10-bis(2-naphthalenyl)anthracene) as host material, a perylene derivative as emitter compound, and NPB as further component. Increased efficiency and/or lifetime compared with an OLED which does not comprise NPB as further component of the emitting layer was thereby achieved.

However, there continues to be interest in OLEDs which have high efficiency and long lifetime, in particular in blue-fluorescent OLEDs having these properties.

Surprisingly, it has now been found that the use of an emitter compound selected from compounds containing at least one condensed aryl group consisting of 2 to 4 aromatic rings condensed with one another in the above-mentioned emitting layers comprising at least 2 host materials enables significantly improved performance data to be achieved. Improved efficiency and an improved lifetime of the device are preferably obtained.

Due to the relative arrangement of the HOMOs of the components of the emitting layer matrix material M1, emitter compound E and matrix material M2 in accordance with

HOMO(M1)>HOMO(E)>HOMO(M2),

the unexpected advantage is achieved that the lifetime of the electronic device is significantly improved. The efficiency of the device and the operating voltage are preferably furthermore improved.

The present invention thus relates to an electronic device comprising anode, cathode, and at least one emitting layer,

where the emitting layer comprises at least one emitter compound E, at least one matrix material M1 and at least one matrix material M2,

where the emitter compound E is selected from compounds containing at least one condensed aryl or heteroaryl group consisting of 2 to 4 aromatic rings condensed with one another,

where the matrix material M2 is selected from compounds containing at a least one anthracene unit,

and where the following applies to the HOMOs of the compounds E, M1 and M2:

HOMO(M1)>HOMO(E)>HOMO(M2).

HOMO here, as generally customary, stands for the highest occupied molecular orbital, in particular for the energetic position of this orbital.

In accordance with the present application, the HOMO values are determined by quantum-chemical measurements, as indicated in detail in the working examples, and are quoted in eV (electron volts). The indication that one HOMO value is greater than the other (for example HOMO (M1) HOMO (E)) is taken to mean that the corresponding HOMO value represents a larger number. For example, the condition HOMO (M1)>HOMO (E) is satisfied for HOMO (M1)=−52 eV and HOMO (E)=−5.3 eV.

The definition that the emitter compound E is selected from compounds containing at least one condensed aryl or heteroaryl group consisting of 2 to 4 aromatic rings condensed with one another is taken to mean that the condensed aryl or heteroaryl group must contain precisely 2, precisely 3 or precisely 4 aromatic or heteroaromatic rings condensed with one another. Aromatic or heteroaromatic rings condensed with one another are aromatic or heteroaromatic rings which share at least one aromatic bond, i.e. at least two aromatic ring atoms bonded to one another, with one another. They may also share more than two aromatic bonds with one another. The condensed aryl or heteroaryl group preferably has 10 to 18 aromatic ring atoms, particularly preferably precisely 10, precisely 14, precisely 16 or precisely 18 aromatic ring atoms. R is preferably a condensed aryl group and not a condensed heteroaryl group. The condensed aryl or heteroaryl group may carry any desired further substituents. The substituents of the group may also form rings here. These rings may also be condensed onto the condensed aryl or heteroaryl group. By definition, however, these condensed-on rings cannot be aromatic or heteroaromatic rings, since the number of aromatic or heteroaromatic rings of the condensed aryl group which are condensed with one another is, as explained above, defined as precisely 2, precisely 3 or precisely 4.

Definitions of chemical groups in accordance with the present application follow.

An aryl group in the sense of this invention contains 6 to 60 aromatic ring atoms; a heteroaryl group in the sense of this invention contains 5 to 60 aromatic ring atoms, at least one of which is a heteroatom. The heteroatoms are preferably selected from N, O and S. This represents the basic definition. If other preferences are indicated in the description of the present invention, for example with respect to the number of aromatic ring atoms or the heteroatoms present, these apply. It is also, as defined above, referred to as condensed aryl or heteroaryl group.

An aryl group or heteroaryl group here is taken to mean either a simple aromatic ring, i.e. benzene, or a simple heteroaromatic ring, for example pyridine, pyrimidine or thiophene, or a condensed (annellated) aromatic or heteroaromatic polycycle, for example naphthalene, phenanthrene, quinoline or carbazole. A condensed (annellated) aromatic or heteroaromatic polycycle in the sense of the present application consists of two or more simple aromatic or heteroaromatic rings condensed with one another.

An aryl or heteroaryl group, which may in each case be substituted by the above-mentioned radicals and which may be linked to the aromatic or heteroaromatic ring system via any desired positions, is taken to mean, in particular, groups derived from benzene, naphthalene, anthracene, phenanthrene, pyrene, dihydropyrene, chrysene, perylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

An aryloxy group in accordance with the definition of the present invention is taken to mean an aryl group, as defined above, which is bonded via an oxygen atom. An analogous definition applies to heteroaryloxy groups.

An aromatic ring system in the sense of this invention contains 6 to 60 C atoms in the ring system. A heteroaromatic ring system in the sense of this invention contains 5 to 60 aromatic ring atoms, at least one of which is a heteroatom. The heteroatoms are preferably selected from N, O and/or S. An aromatic or heteroaromatic ring system in the sense of this invention is intended to be taken to mean a system which does not necessarily contain only aryl or heteroaryl groups, but instead in which, in addition, a plurality of aryl or heteroaryl groups may be connected by a non-aromatic unit (preferably less than 10% of the atoms other than H), such as, for example, an sp³-hybridised C, Si, N or O atom, an sp²-hybridised C or N atom or an sp-hybridised C atom. Thus, for example, systems such as 9,9′-spirobifluorene, 9,9′-diarylfluorene, triarylamine, diaryl ether, stilbene, etc., are also intended to be taken to be aromatic ring systems in the sense of this invention, as are systems in which two or more aryl groups are connected, for example, by a linear or cyclic alkyl, alkenyl or alkynyl group or by a silyl group. Furthermore, systems in which two or more aryl or heteroaryl groups are linked to one another via single bonds are also taken to be aromatic or heteroaromatic ring systems in the sense of this invention, such as, for example, systems such as biphenyl, terphenyl or diphenyl-triazine.

An aromatic or heteroaromatic ring system having 5-60 aromatic ring atoms, which may in each case also be substituted by radicals as defined above and which may be linked to the aromatic or heteroaromatic group via any desired positions, is taken to mean, in particular, groups derived from benzene, naphthalene, anthracene, benzanthracene, phenanthrene, benzophenanthrene, pyrene, chrysene, perylene, fluoranthene, naphthacene, pentacene, benzopyrene, biphenyl, biphenylene, terphenyl, terphenylene, quaterphenyl, fluorene, spirobifluorene, dihydrophenanthrene, dihydropyrene, tetrahydropyrene, cis- or trans-indenofluorene, truxene, isotruxene, spirotruxene, spiroisotruxene, furan, benzofuran, isobenzo-dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole, or combinations of these groups.

For the purposes of the present invention, a straight-chain alkyl group having 1 to 40 C atoms or a branched or cyclic alkyl group having 3 to 40 C atoms or an alkenyl or alkynyl group having 2 to 40 C atoms, in which, in addition, individual H atoms or CH₂ groups may be substituted by the groups mentioned above under the definition of the radicals, is preferably taken to mean the radicals methyl, ethyl, n-propyl, i-propyl, n-butyl, i-butyl, s-butyl, t-butyl, 2-methylbutyl, n-pentyl, s-pentyl, cyclopentyl, neopentyl, n-hexyl, cyclohexyl, neohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl. An alkoxy or thioalkyl group having 1 to 40 C atoms is preferably taken to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy, 2,2,2-trifluoroethoxy, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclo-octylthio, 2-ethylhexylthio, trifluoromethylthio, pentafluoroethylthio, 2,2,2-trifluoroethylthio, ethenylthio, propenylthio, butenylthio, pentenylthio, cyclo-pentenylthio, hexenylthio, cyclohexenylthio, heptenylthio, cyclo-heptenylthio, octenylthio, cyclooctenylthio, ethynylthio, propynylthio, butynythio, pentynylthio, hexynylthio, heptynylthio or octynylthio.

The formulation that two or more radicals may form a ring with one another is, for the purposes of the present application, intended to be taken to mean, inter alia, that the two radicals are linked to one another by a chemical bond. This is illustrated by the following scheme:

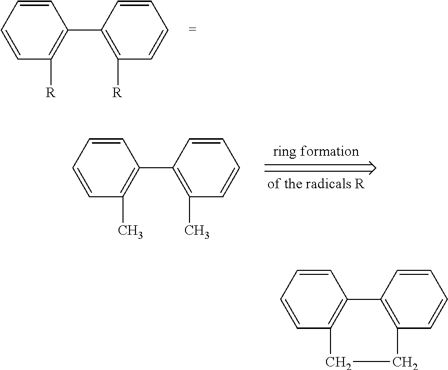

Furthermore, however, the above-mentioned formulation is also intended to be taken to mean that, in the case where one of the two radicals represents hydrogen, the second radical is bonded at the position to which the hydrogen atom was bonded, with formation of a ring. This is illustrated by the following scheme:

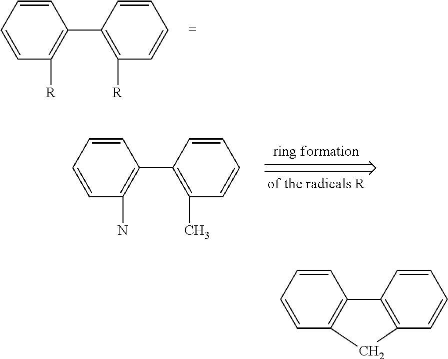

According to a preferred embodiment of the invention, the emitter compound E is a small organic molecule. It is preferably not a polymer, dendrimer or oligomer. It preferably has a molecular weight of 200 to 2000 g/mol, particularly preferably 250 to 1500 g/mol and very particularly preferably of 300 to 1000 g/mol.

The emitter compound E preferably contains no condensed aryl or heteroaryl group having more than four aromatic rings condensed with one another.

The emitter compound E furthermore preferably contains no arylamino group. It particularly preferably contains no amino group. An arylamino group in the sense of this application is taken to mean a group in which at least one aryl group or heteroaryl group is bonded to a trivalent nitrogen atom. The way in which the group is built up further, or what further groups it contains, is unimportant for the definition.

The emitter compound E furthermore preferably contains at least one group selected from pyrenyl groups, anthracenyl groups, fluorenyl groups and indenofluorenyl groups. The fluorenyl group here preferably contains one, two or three condensed-on benzene rings, so that a benzofluorenyl group forms. Thebenzene rings here are preferably condensed onto benzene rings of the fluorenyl group. The indenofluorenyl group furthermore preferably contains one, two or three condensed-on benzene rings, so that a benzoindenofluorene group forms. The benzene rings here are preferably condensed onto benzene rings of the indenofluorene group.

Particularly preferred emitter compounds E are selected from the indeno-fluorenamines disclosed in WO 2006/108497, from the anthracene derivatives disclosed in WO 2007/065678, from the dibenzoindenofluorenes disclosed in WO 2007/140847, from the monobenzoindenofluorenes disclosed in WO 2008/006449, from the diindenoanthracenes disclosed in WO 2009/127307, from the benzoindenofluorenes containing large condensed aryl groups disclosed in WO 2010/012328, from the multiply bridged condensed aromatic compounds disclosed in WO 2010/049050, and from the benzoindenofluorenamines disclosed in the as yet unpublished application EP 12006239.3. Of these, particular preference is given to the benzoindenofluorenes containing large condensed aryl groups disclosed in the said WO 2010/012328.

The emitter compound E is preferably a compound of the following formula (I)

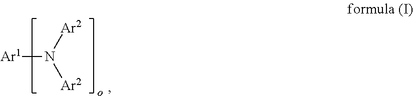

where:
Ar¹ is an aromatic or heteroaromatic ring system having 10 to 40 aromatic ring atoms, containing at least one condensed aryl or heteroaryl group consisting of 2 to 4 aromatic rings condensed with one another, where the aromatic or heteroaromatic ring system may be substituted by one or more radicals R¹;
Ar² is an aromatic or heteroaromatic ring system having 6 to 40 aromatic ring atoms, which may be substituted by one or more radicals R¹;
R¹ is on each occurrence, identically or differently, H, D, F, C(═O)R², CN, Si(R²)₃, N(R²)₂, P(═O)(R²)₂, S(═O)R², S(═O)₂R², a straight-chain alkyl or alkoxy group having 1 to 20 C atoms or a branched or cyclic alkyl or alkoxy group having 3 to 20 C atoms or an alkenyl or alkynyl group having 2 to 20 C atoms, where the above-mentioned groups may each be substituted by one or more radicals R² and where one or more CH₂ groups in the above-mentioned groups may be replaced by —R²C═CR²—, —C≡C—, Si(R²)₂, C═O, C═S, C═NR², —C(═O)O—, —C(═O)NR²—, NR², P(═O)(R²), —O—, —S—, SO or SO₂ and where one or more H atoms in the above-mentioned groups may be replaced by D, F or CN, or an aromatic or heteroaromatic ring system having 5 to 30 aromatic ring atoms, which may in each case be substituted by one or more radicals R², or an aryloxy or heteroaryloxy group having 5 to 30 aromatic ring atoms, which may be substituted by one or more radicals R², where two or more radicals R¹ may be linked to one another and may form a ring;
R² is on each occurrence, identically or differently, H, D, F or an aliphatic, aromatic or heteroaromatic organic radical having 1 to 20 C

atoms, in which, in addition, one or more H atoms may be replaced by D or F; two or more substituents R² here may be linked to one another and may form a ring; and

o is 0, 1, 2, 3 or 4.

In formula (I), o is preferably equal to 0, 1 or 2, particularly preferably equal to 0 or 1, very particularly preferably equal to 0.

Furthermore preferably, Ar¹ in formula (I) is selected from the following groups:

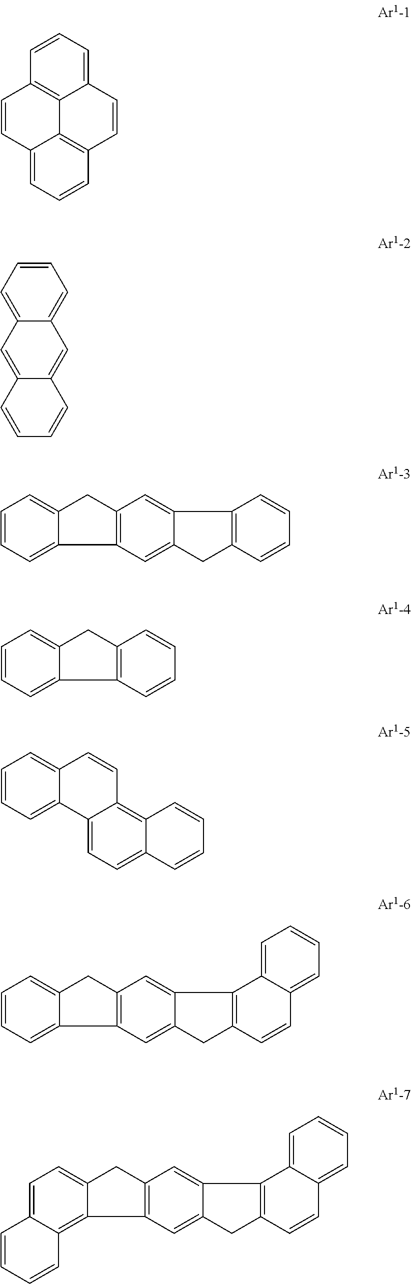

where the groups may be substituted at all free positions by one or more radicals R¹, and

where the groups of the formula Ar¹-3 and Ar¹-4 must contain at least one additional condensed-on aromatic ring which is condensed onto one of the the six-membered rings.

The groups of the formula Ar¹-3 and Ar¹-4 preferably contain two or three additional condensed-on aromatic rings, which can be condensed onto a single six-membered ring or onto a plurality of different six-membered rings. The condensed-on aromatic rings are preferably six-membered rings.

In combination with the choice of Ar¹ from one of the above-mentioned groups Ar¹-1 to Ar¹-7, o in formula (I) is preferably equal to 0.

Particular preference is given to compounds of the formula (I), selected from the formulae (I-1) to (I-31), where the aromatic systems may each be substituted by one or more radicals R¹:

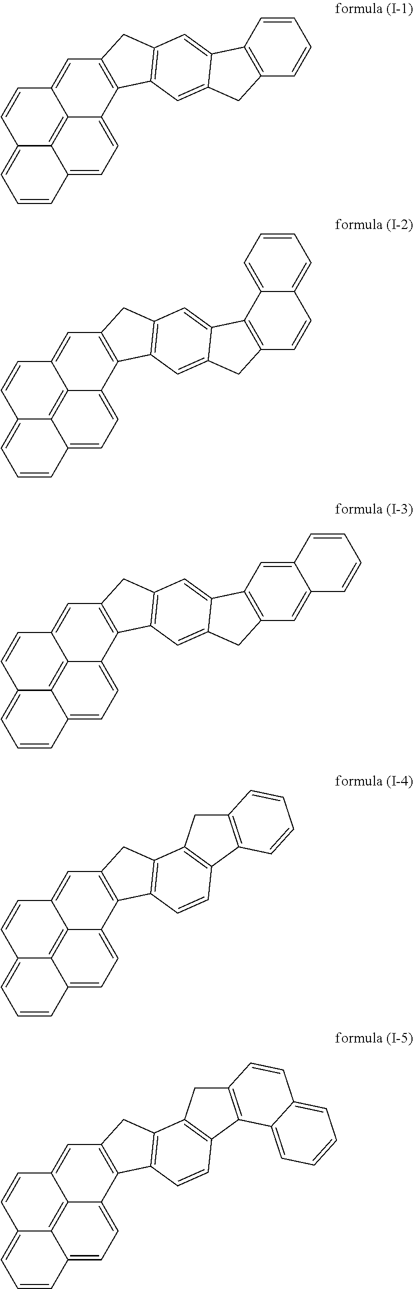

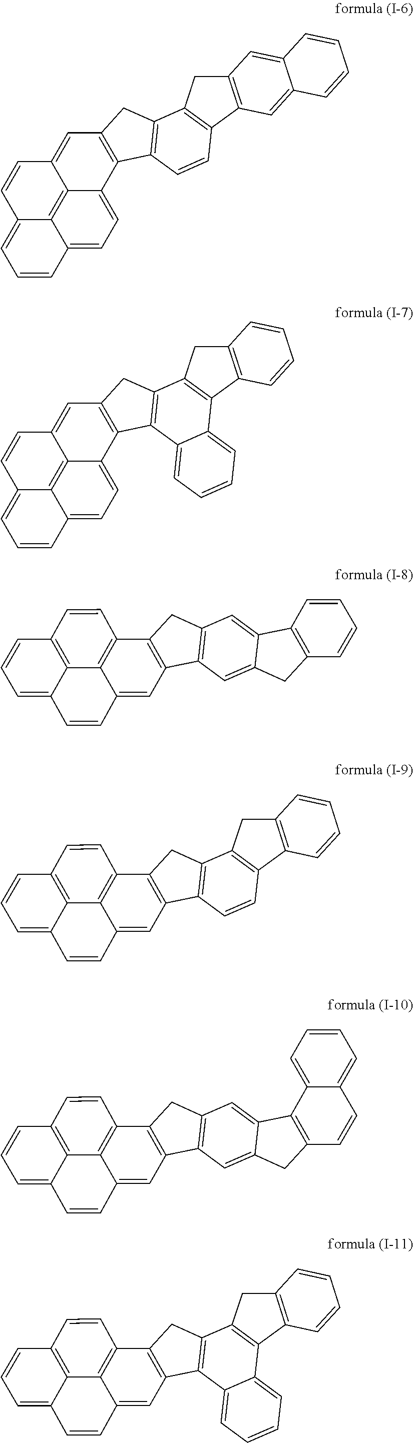

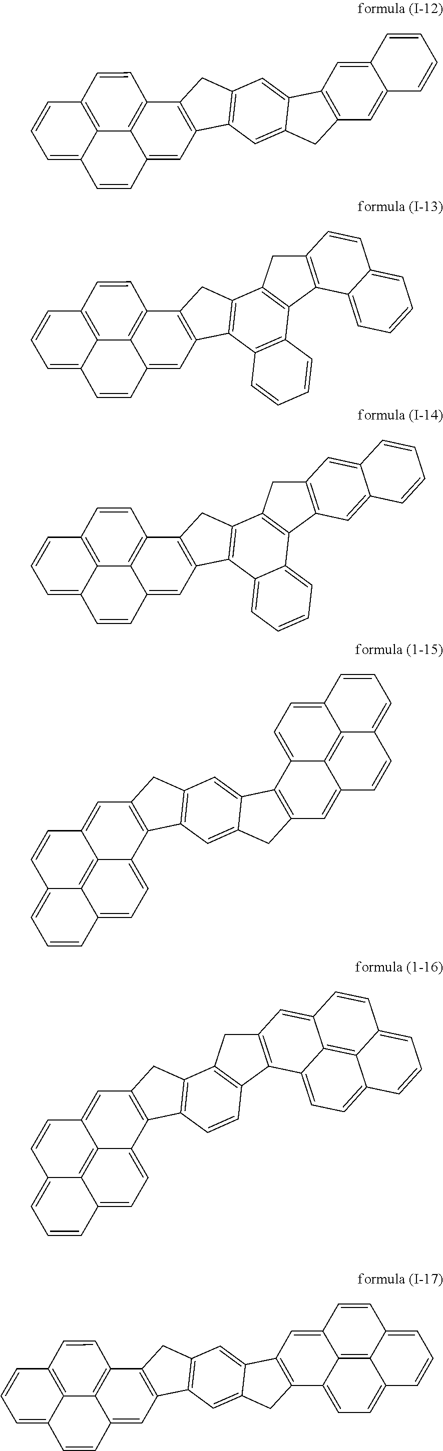

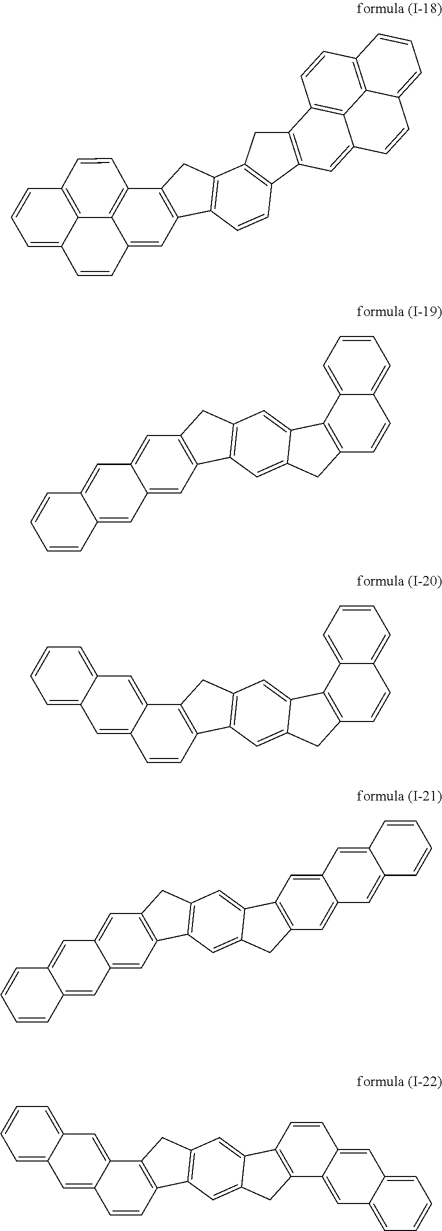

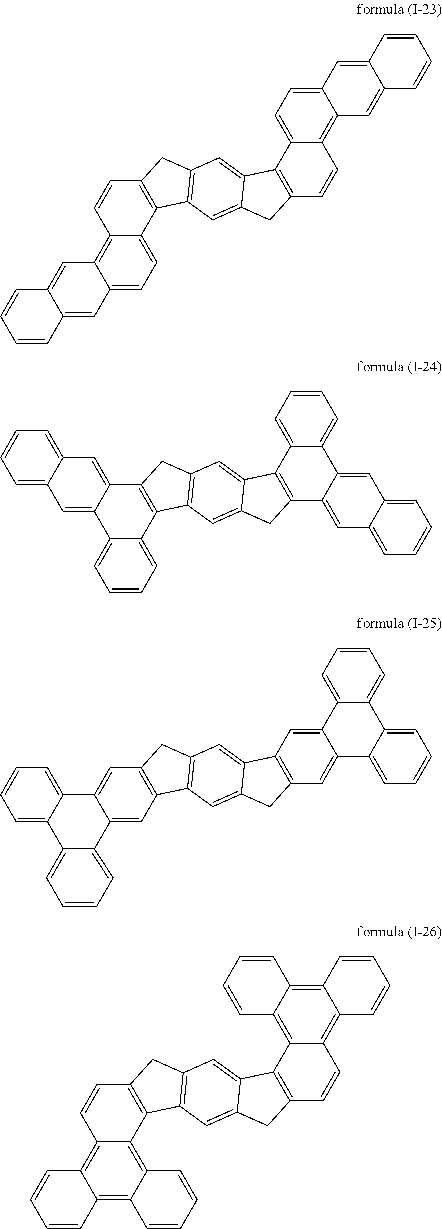

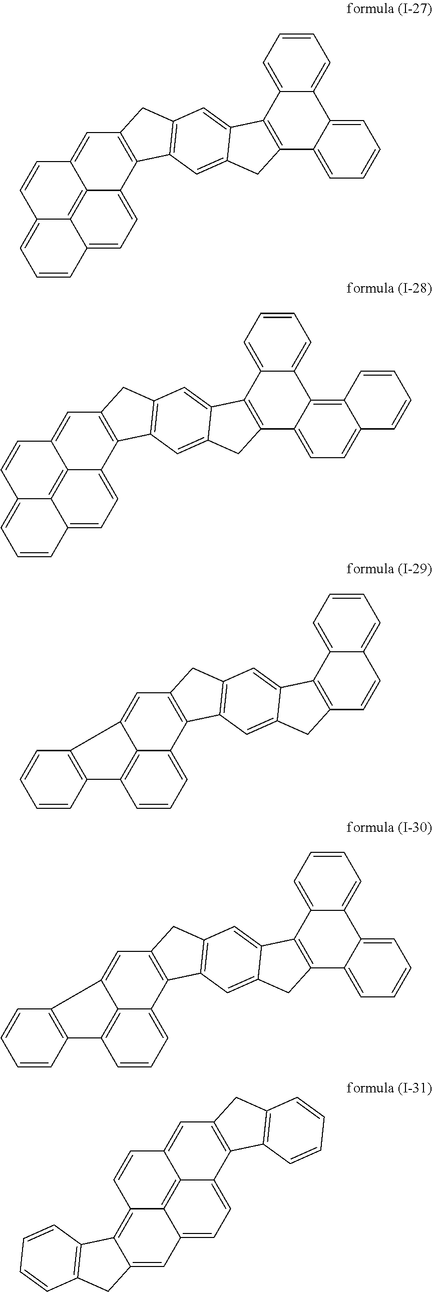

According to a preferred embodiment of the invention, the emitter compound E is a fluorescent compound.

For the purposes of the present application, fluorescence is taken to mean emission from a transition from an excited singlet state.

The HOMO of the emitter compound E is preferably between −7.9 eV and −3.9 eV, preferably between −6.4 eV and −4.1 eV and very particularly preferably between −6.1 eV and −5.1 eV.

According to a preferred embodiment of the invention, the matrix material M1 is a small organic molecule. It is preferably not a polymer, dendrimer or oligomer. It preferably has a molecular weight of 200 to 2000 g/mol, particularly preferably 250 to 1500 g/mol and very particularly preferably of 300 to 1000 g/mol.

The matrix material M1 is preferably selected from a triarylamino compound. A triarylamino compound in accordance with the present application is taken to mean a compound in which three aryl or heteroaryl groups are bonded to a common nitrogen atom. The aryl or heteroaryl groups which are bonded to the common nitrogen atom may be connected to one another via divalent groups or single bonds. They are preferably not connected to one another. The triarylamino compound may contain any desired further groups and substituents besides the said structural unit.

The matrix material M1 is particularly preferably selected from a monotriarylamino compound. A monotriarylamino compound is taken to mean a compound which contains precisely one triarylamino group, as defined above. It contains no further triarylamino groups. It preferably contains no further amino groups.

The matrix material M1 is particularly preferably selected from compounds of the formula (II)

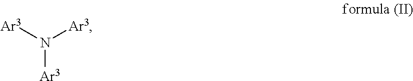

where:
Ar³ is on each occurrence, identically or differently, an aromatic or heteroaromatic ring system having 5 to 50 aromatic ring atoms, which may be substituted by one or more radicals R³; and
R³ is on each occurrence, identically or differently, H, D, F, C(═O)R⁴, CN, Si(R⁴)₃, P(═O)(R⁴)₂, S(═O)R⁴, S(═O)₂R⁴, a straight-chain alkyl or alkoxy group having 1 to 20 C atoms or a branched or cyclic alkyl or alkoxy group having 3 to 20 C atoms or an alkenyl or alkynyl group having 2 to 20 C atoms, where the above-mentioned

groups may each be substituted by one or more radicals R⁴ and where one or more CH₂ groups in the above-mentioned groups may be replaced by —R⁴C═CR⁴—, —C≡C—, Si(R⁴)₂, C═O, C═S, C═NR⁴, —C(═O)O—, —C(═O)NR⁴—, P(═O)(R⁴), —O—, —S—, SO or SO₂ and where one or more H atoms in the above-mentioned groups may be replaced by D, F or CN, or an aromatic or heteroaromatic ring system having 5 to 30 aromatic ring atoms, which may in each case be substituted by one or more radicals R⁴, or an aryloxy or heteroaryloxy group having 5 to 30 aromatic ring atoms, which may be substituted by one or more radicals R⁴, where two or more radicals R³ may be linked to one another and may form a ring;
R⁴ is on each occurrence, identically or differently, H, D, F or an aliphatic, aromatic or heteroaromatic organic radical having 1 to 20 C atoms, in which, in addition, one or more H atoms may be replaced by D or F; two or more substituents R⁴ here may be linked to one another and may form a ring.

Ar³ is preferably an aromatic ring system having 6 to 30 aromatic ring atoms, which may be substituted by one or more radicals R³. Ar³ particularly preferably contains a group selected from fluorene, indenofluorene, spirobifluorene, phenyl, biphenyl, terphenyl or naphthyl, which is substituted by R³ or unsubstituted.

Ar³ furthermore preferably contains no condensed aryl group having more than 14 aromatic ring atoms, Ar³ particularly preferably contains no condensed aryl group having more than 10 aromatic ring atoms.

Ar³ furthermore preferably contains no condensed heteroaryl group having more than 14 aromatic ring atoms, Ar³ particularly preferably contains no condensed heteroaryl group having more than 10 aromatic ring atoms.

The matrix material M1 is preferably selected from compounds of the formulae (II-1) to (II-6)

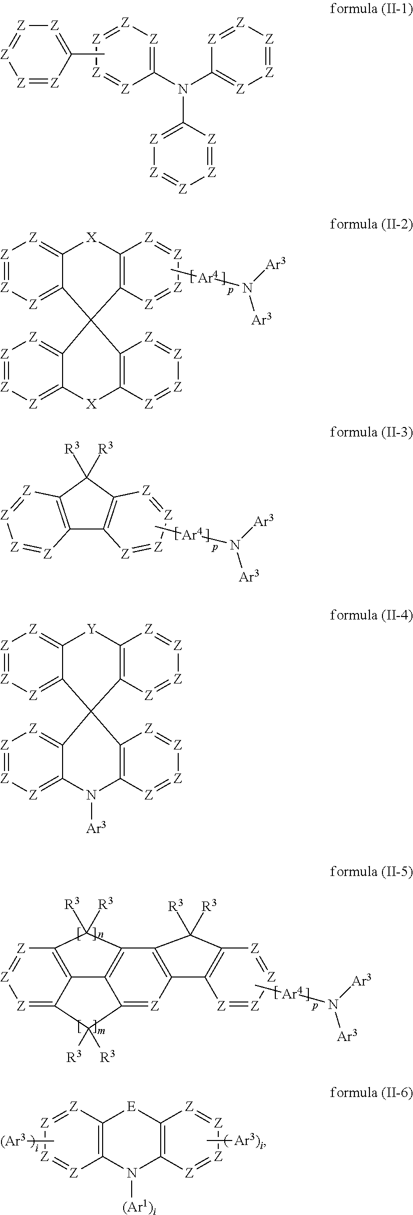

where:
Z is on each occurrence, identically or differently, N or CR³, where Z is equal to C if a substituent is bonded;
X is on each occurrence, identically or differently, a single bond, O, S, Se, BR³, C(R³)₂, Si(R³)₂, NR³, PR³, C(R³)₂—C(R³)₂, or CR³═CR³;
Y is a single bond, O, S, Se, BR³, C(R³)₂, Si(R³)₂, NR³, PR³, C(R³)₂—C(R³)₂, or CR³═CR³;
E is O, S, Se, BR³, C(R³)₂, Si(R³)₂, NR³, PR³, C(R³)₂—C(R³)₂, or CR³═CR³;
Ar³ is defined as above;
Ar⁴ is an aromatic or heteroaromatic ring system having 6 to 18 aromatic ring atoms, which may be substituted by one or more radicals R³;
R³ is defined as above;
i is on each occurrence, identically or differently, 0 or 1, where the sum of all i is at least equal to 1;
p is equal to 0 or 1;
m, n are, identically or differently, 0 or 1, where the sum of m and n is equal to 1 or 2.

For the above-mentioned formulae (II-1) to (II-6), it is preferred that not more than three groups Z in a ring are equal to N. It is generally preferred that Z is equal to CR³.

The group X is on each occurrence preferably selected, identically or differently, from a single bond, C(R³)₂, O and S, it is particularly preferably a single bond.

The group Y is preferably selected from O and C(R³)₂, it is particularly preferably O.

The group E is preferably selected from C(R³)₂, O and S, it is particularly preferably C(R³)₂.

The group Ar³ is preferably selected on each occurrence, identically or differently, from aromatic or heteroaromatic ring systems having 6 to 30 aromatic ring atoms, which may be substituted by one or more radicals R³. Ar³ is particularly preferably selected from aryl or heteroaryl groups having 6 to 18 aromatic ring atoms, which may be substituted by one or more radicals R³.

Examples of compounds which are employed as matrix material M1 in the electronic device according to the invention are shown below:

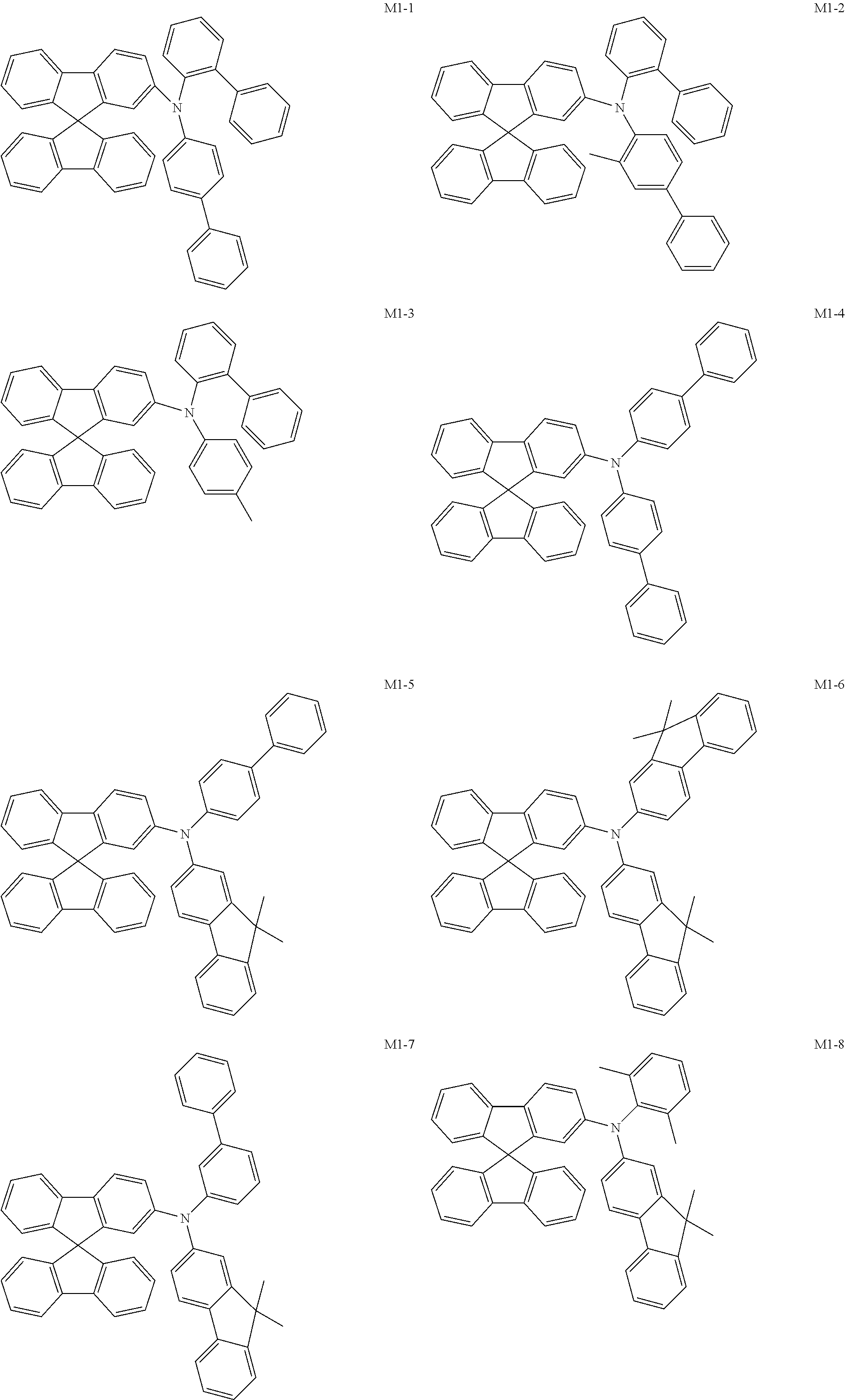

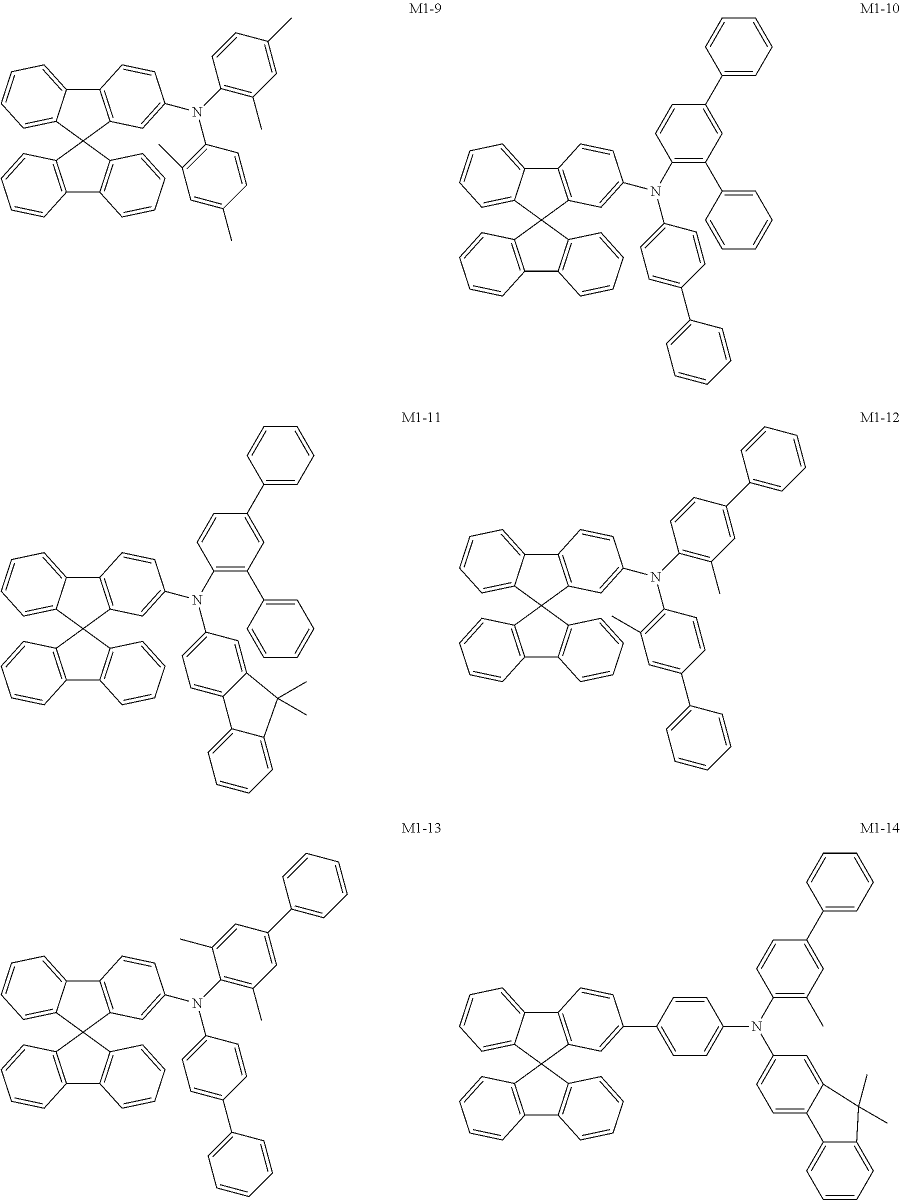

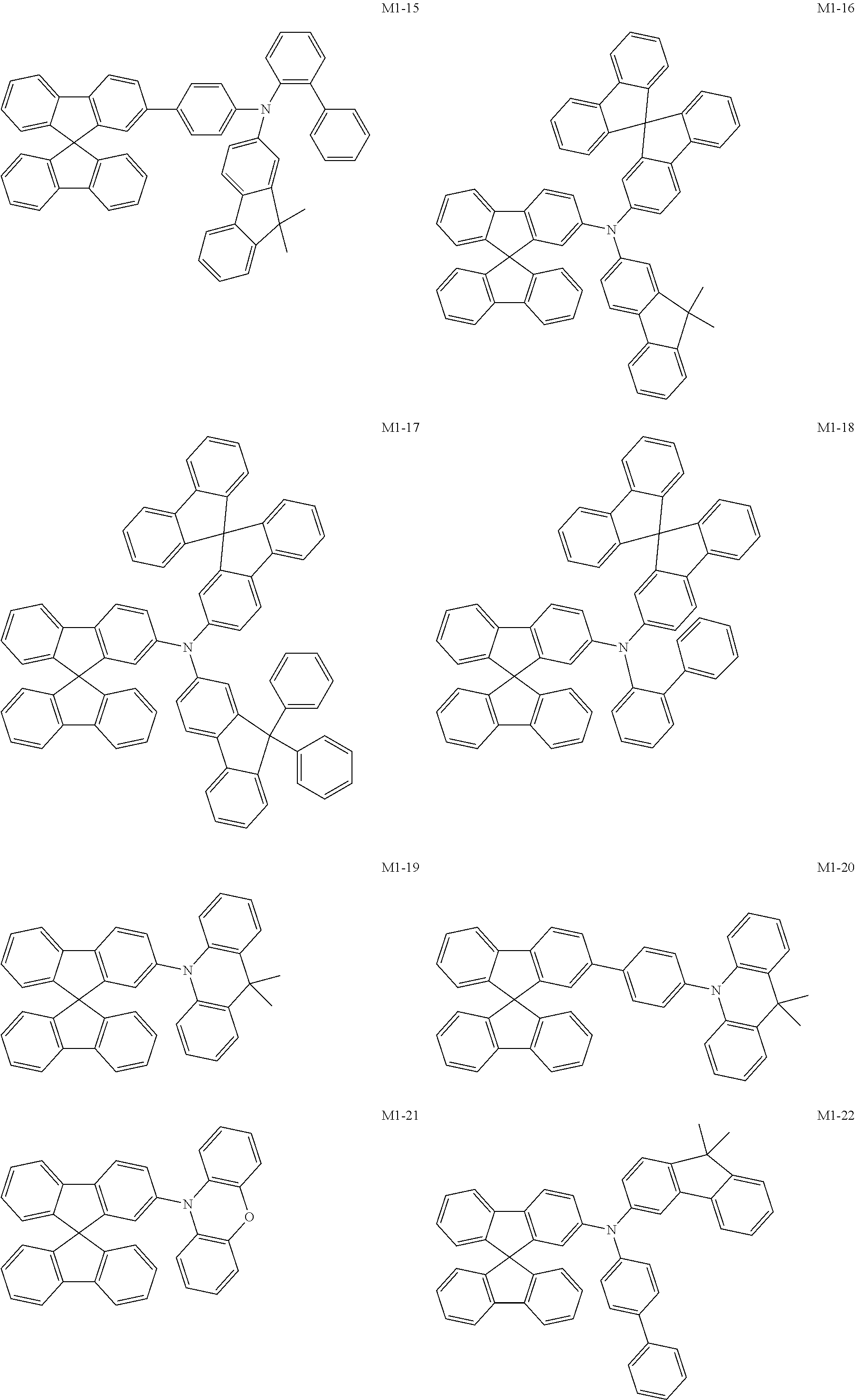

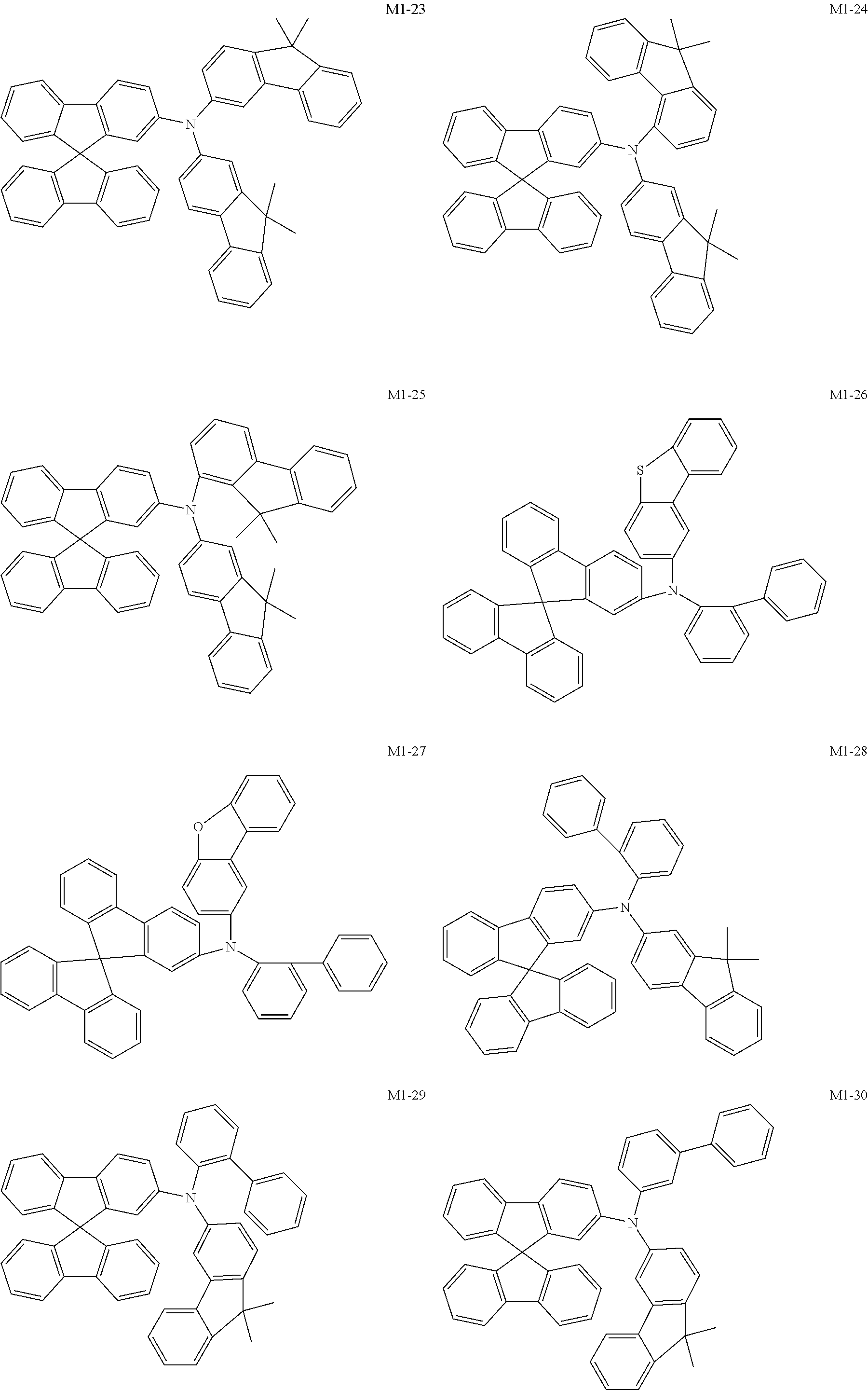

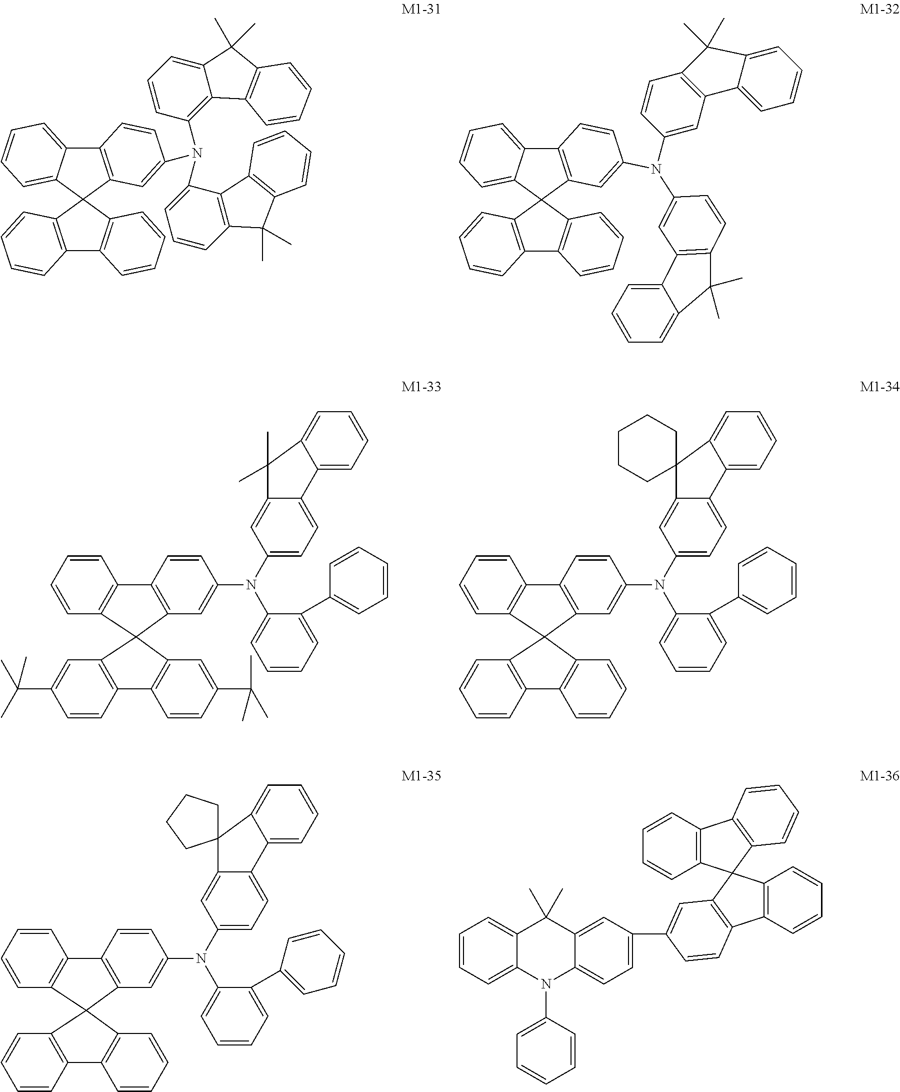

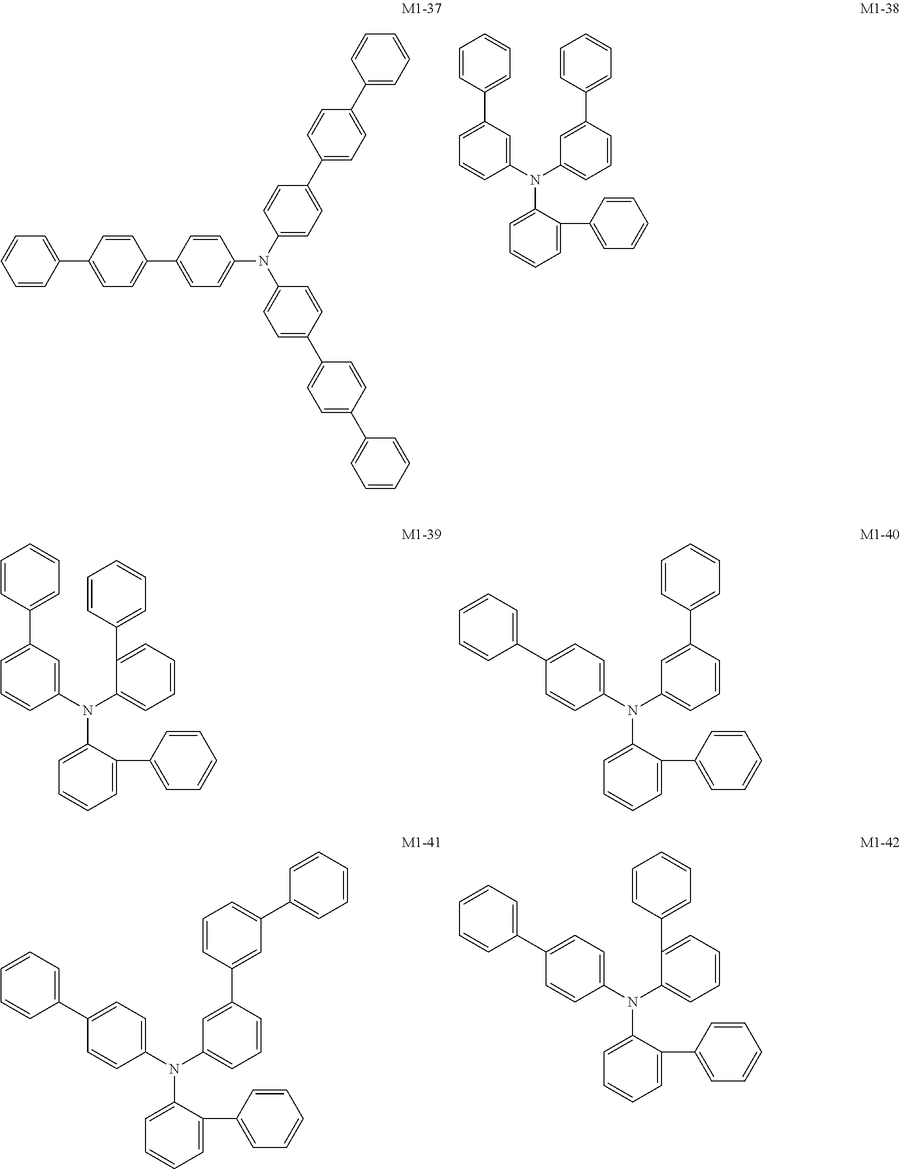 [SMILES: c1ccc(-c2ccc(-c3ccc(N(c4ccc(-c5ccc(-c6ccccc6)cc5)cc4)c4ccc(-c5ccc(-c6ccccc6)cc5)cc4)cc3)cc2)cc1 ; c1ccc(-c2cccc(N(c3cccc(-c4ccccc4)c3)c3ccccc3-c3ccccc3)c2)cc1 ; c1ccc(-c2cccc(N(c3ccccc3-c3ccccc3)c3ccccc3-c3ccccc3)c2)cc1 ; c1ccc(-c2ccc(N(c3cccc(-c4ccccc4)c3)c3ccccc3-c3ccccc3)cc2)cc1 ; c1ccc(-c2ccc(N(c3cccc(-c4cccc(-c5ccccc5)c4)c3)c3ccccc3-c3ccccc3)cc2)cc1 ; c1ccc(-c2ccc(N(c3ccccc3-c3ccccc3)c3ccccc3-c3ccccc3)cc2)cc1]

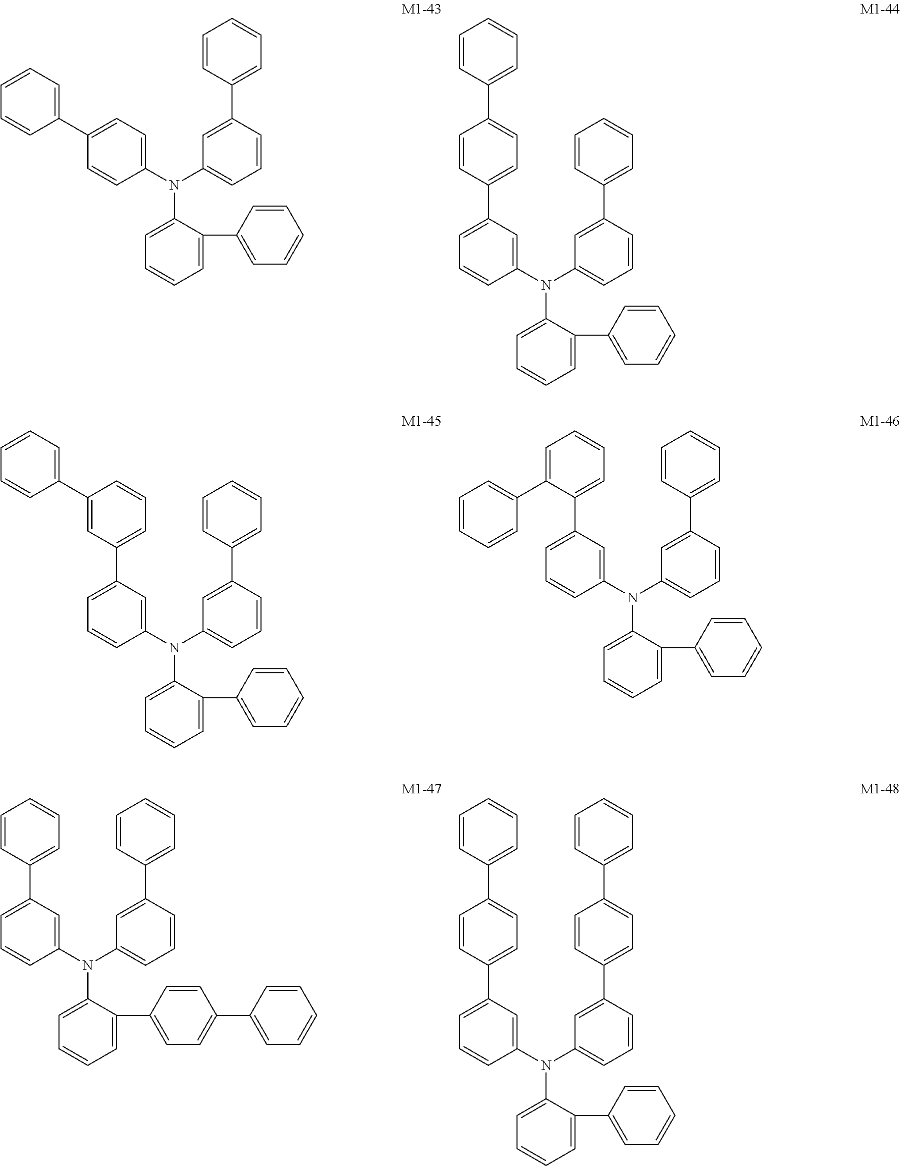 [SMILES: c1ccc(-c2ccc(N(c3cccc(-c4ccccc4)c3)c3ccccc3-c3ccccc3)cc2)cc1 ; c1ccc(-c2ccc(-c3cccc(N(c4cccc(-c5ccccc5)c4)c4ccccc4-c4ccccc4)c3)cc2)cc1 ; c1ccc(-c2cccc(-c3cccc(N(c4cccc(-c5ccccc5)c4)c4ccccc4-c4ccccc4)c3)c2)cc1 ; c1ccc(-c2cccc(N(c3cccc(-c4ccccc4-c4ccccc4)c3)c3ccccc3-c3ccccc3)c2)cc1 ; c1ccc(-c2ccc(-c3ccccc3N(c3cccc(-c4ccccc4)c3)c3cccc(-c4ccccc4)c3)cc2)cc1 ; c1ccc(-c2ccc(-c3cccc(N(c4cccc(-c5ccc(-c6ccccc6)cc5)c4)c4ccccc4-c4ccccc4)c3)cc2)cc1]

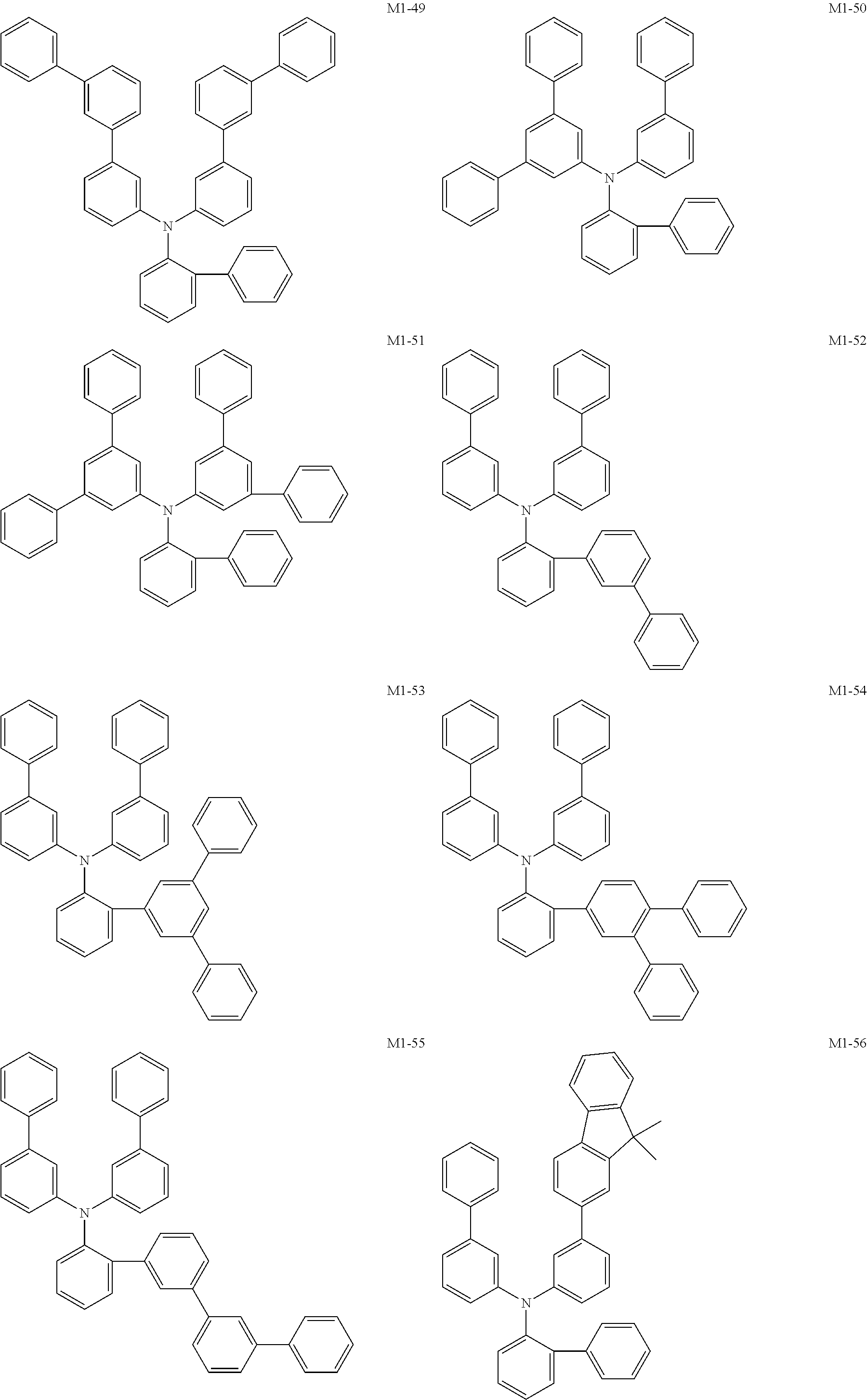

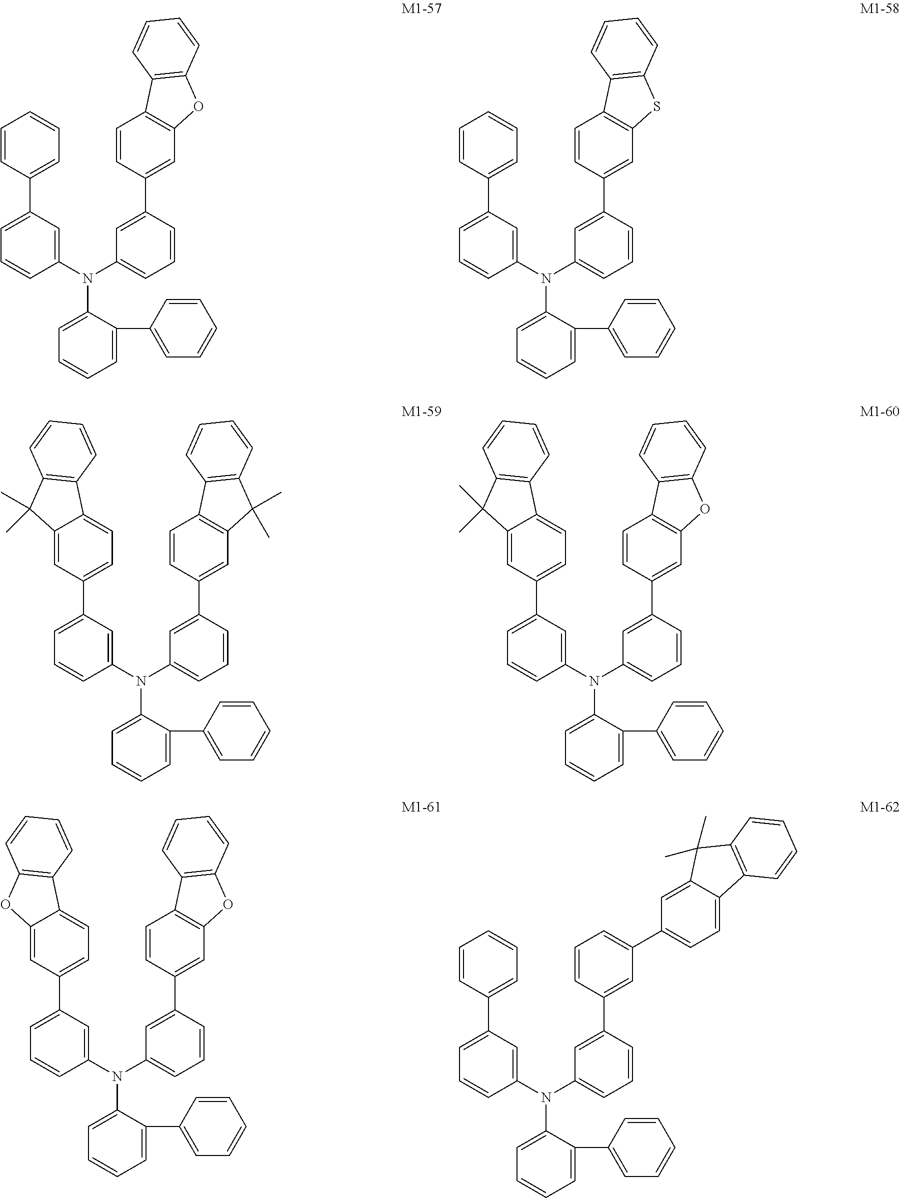

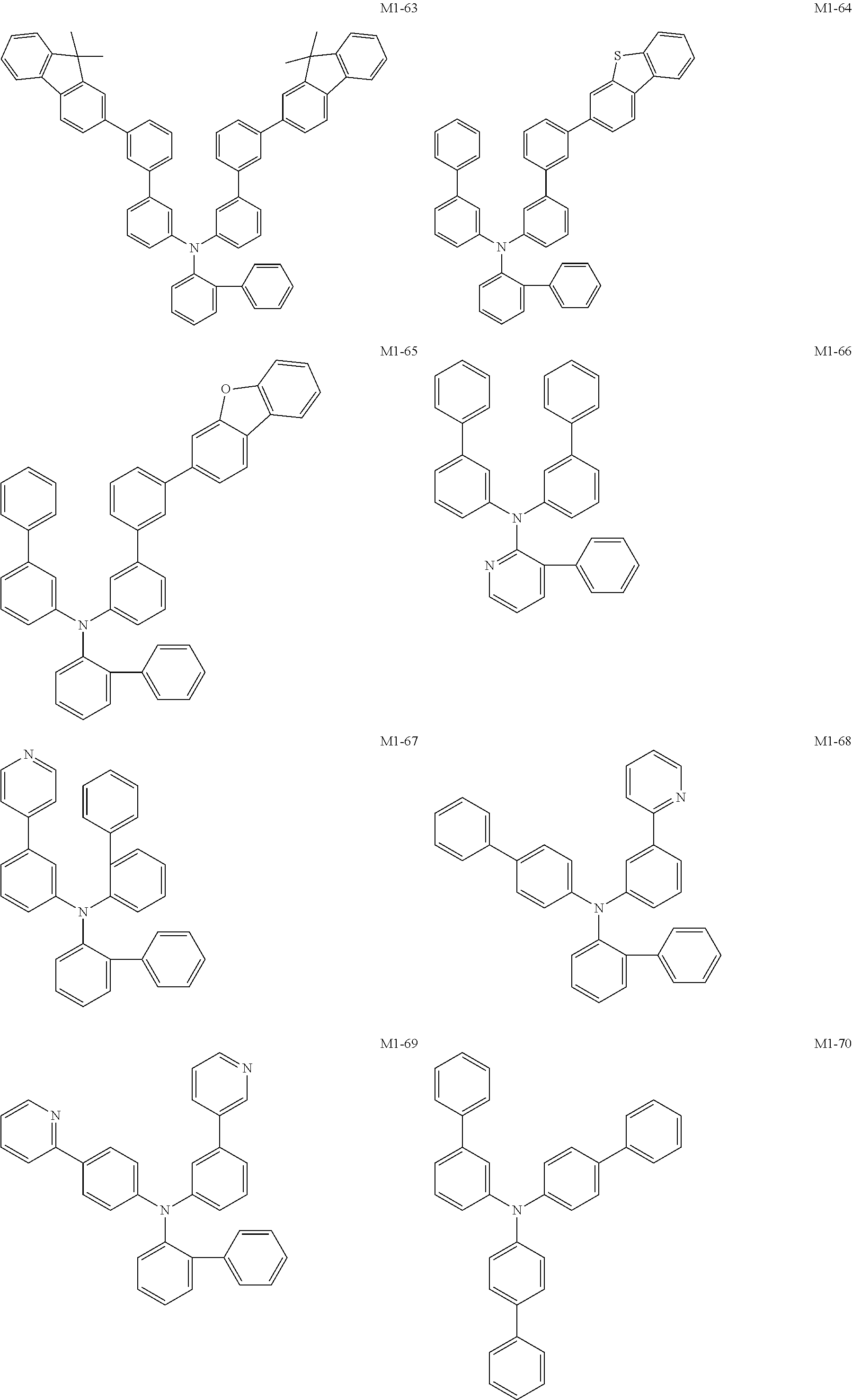

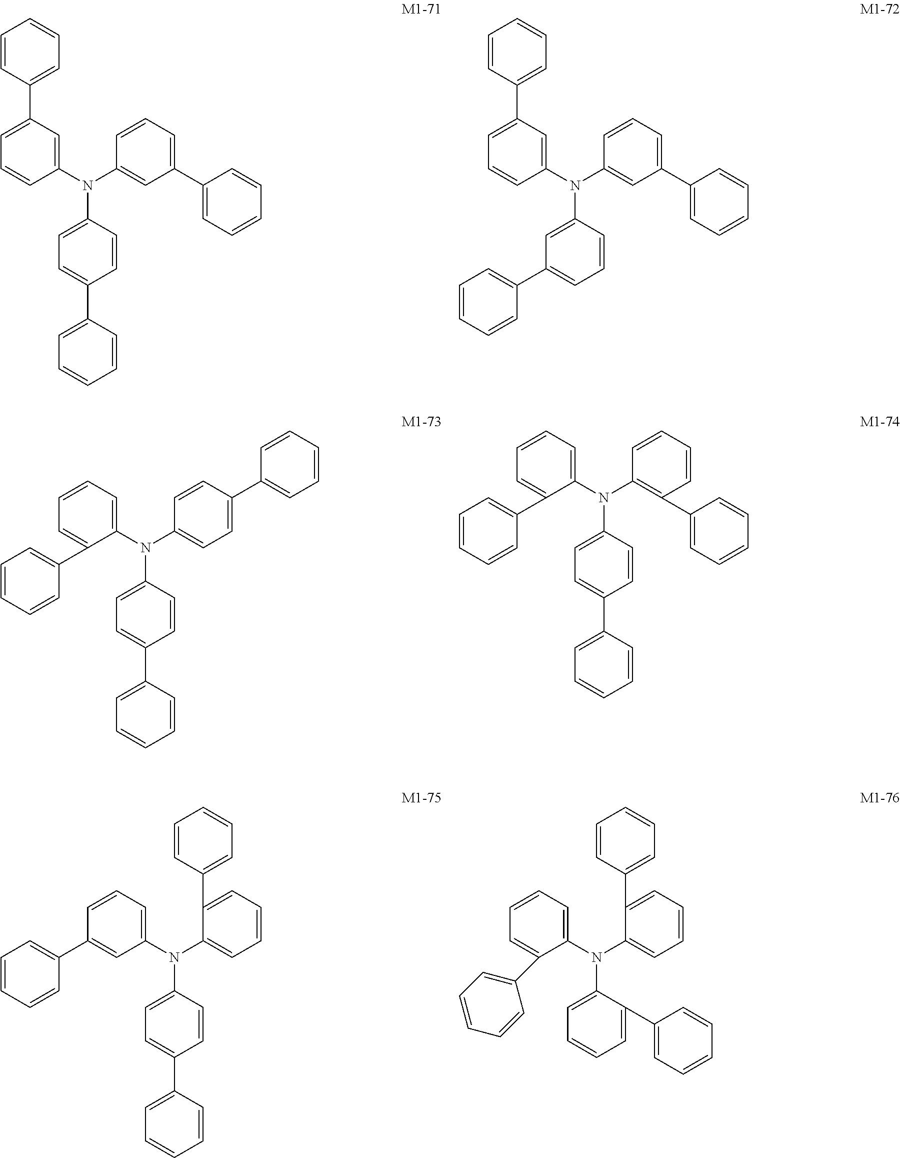 [SMILES: c1ccc(-c2ccc(N(c3cccc(-c4ccccc4)c3)c3cccc(-c4ccccc4)c3)cc2)cc1 ; c1ccc(-c2cccc(N(c3cccc(-c4ccccc4)c3)c3cccc(-c4ccccc4)c3)c2)cc1 ; c1ccc(-c2ccc(N(c3ccc(-c4ccccc4)cc3)c3ccccc3-c3ccccc3)cc2)cc1 ; c1ccc(-c2ccc(N(c3ccccc3-c3ccccc3)c3ccccc3-c3ccccc3)cc2)cc1 ; c1ccc(-c2ccc(N(c3cccc(-c4ccccc4)c3)c3ccccc3-c3ccccc3)cc2)cc1 ; c1ccc(-c2ccccc2N(c2ccccc2-c2ccccc2)c2ccccc2-c2ccccc2)cc1]

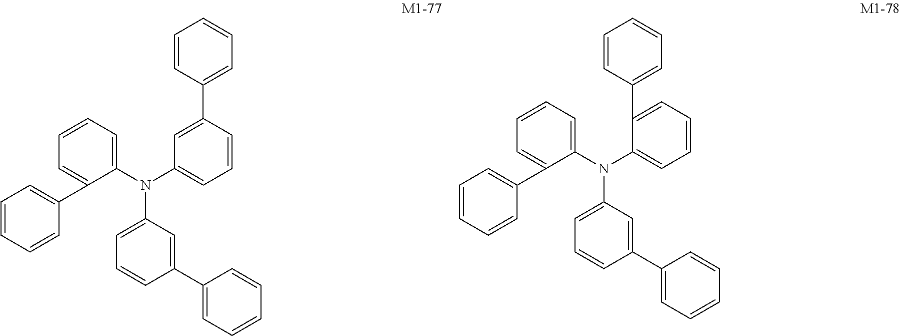 [SMILES: c1ccc(-c2cccc(N(c3cccc(-c4ccccc4)c3)c3ccccc3-c3ccccc3)c2)cc1 ; c1ccc(-c2cccc(N(c3ccccc3-c3ccccc3)c3ccccc3-c3ccccc3)c2)cc1]

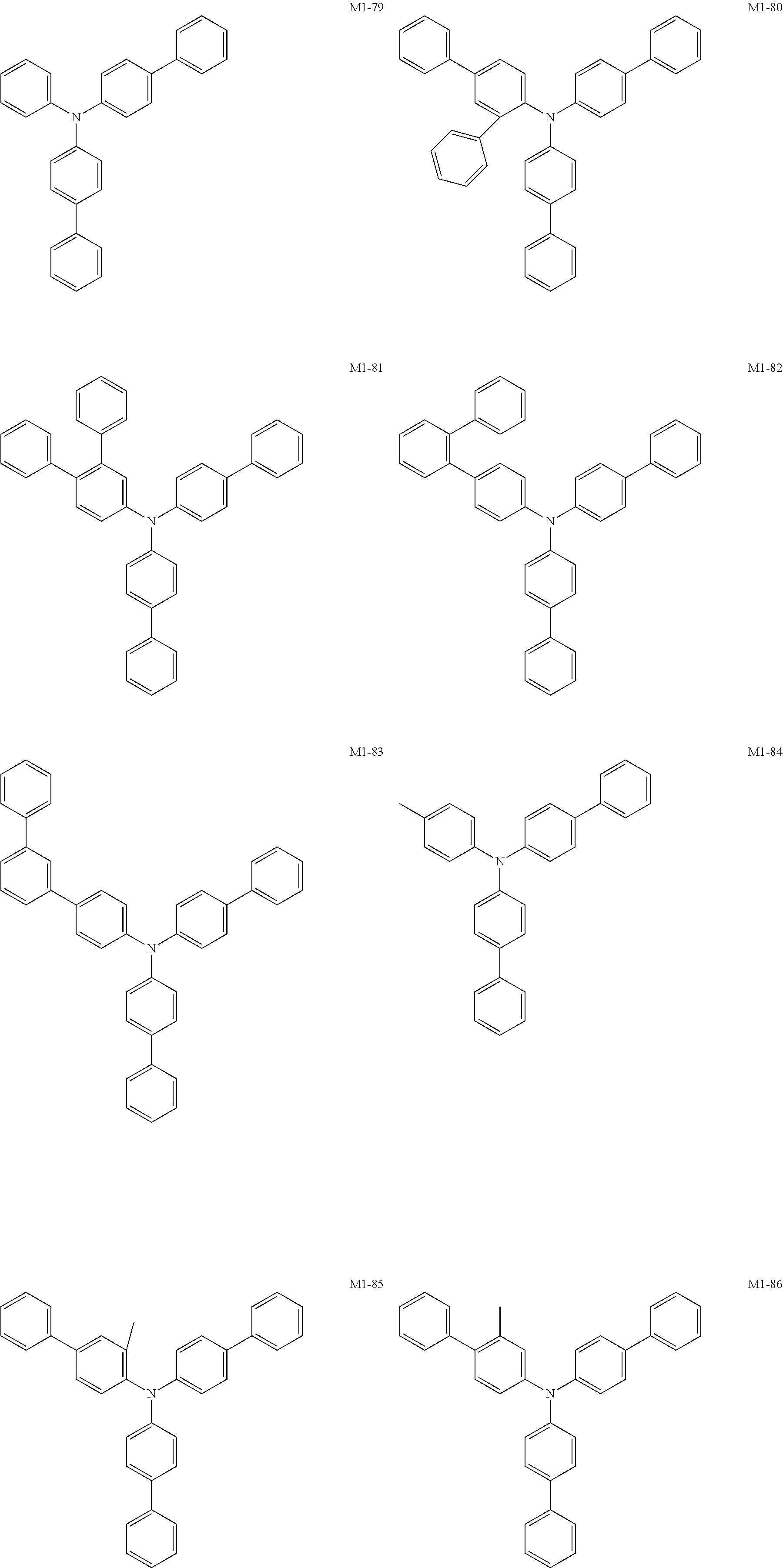

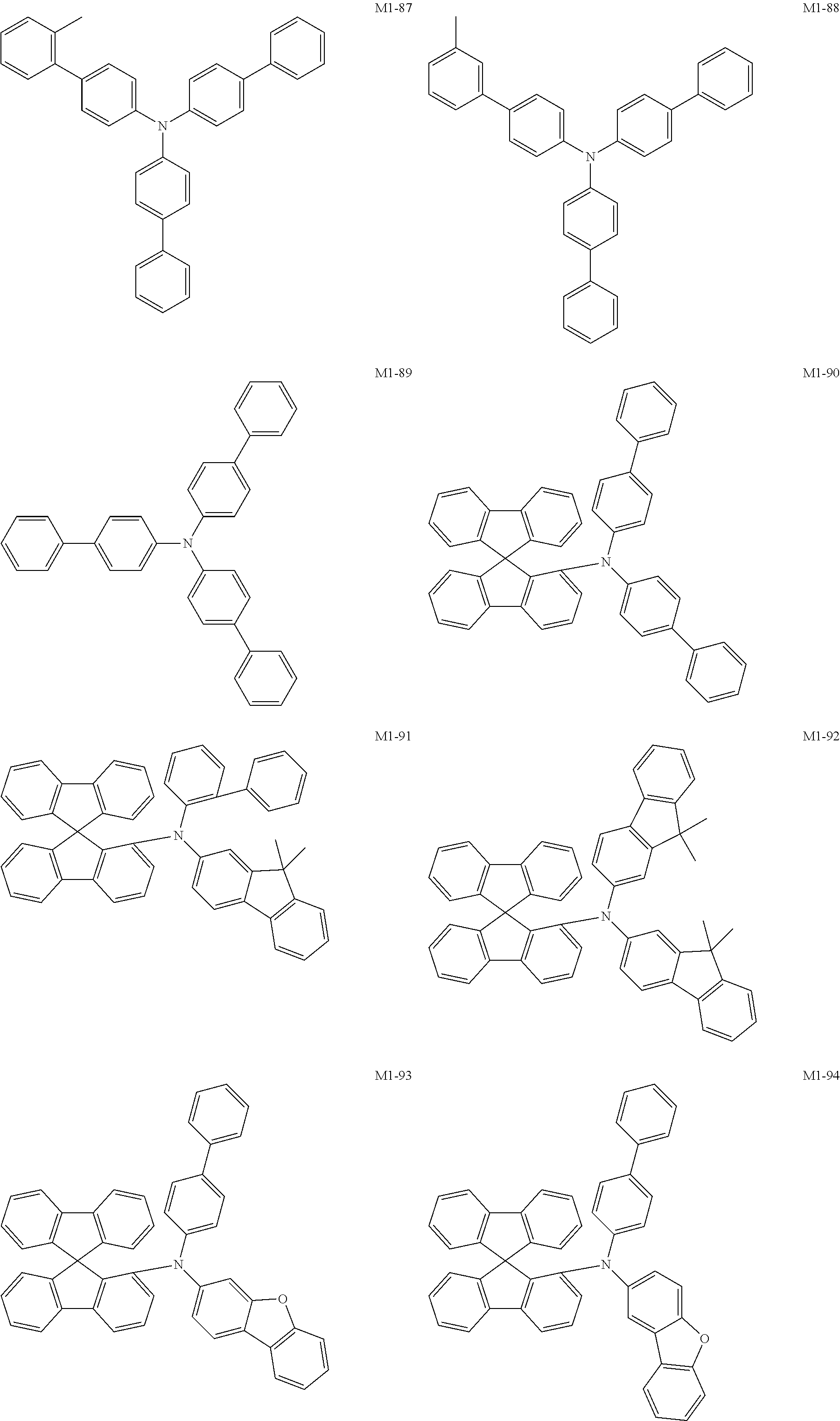

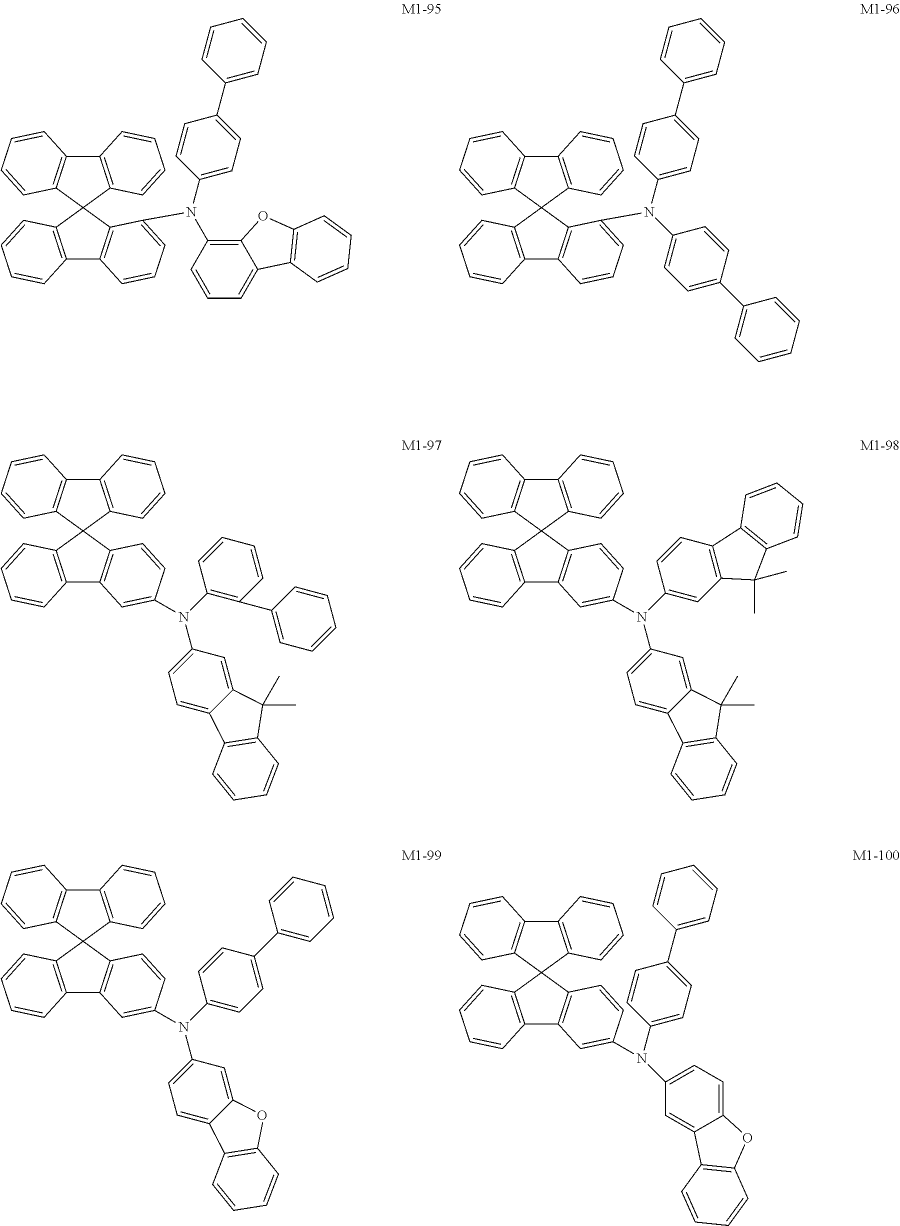

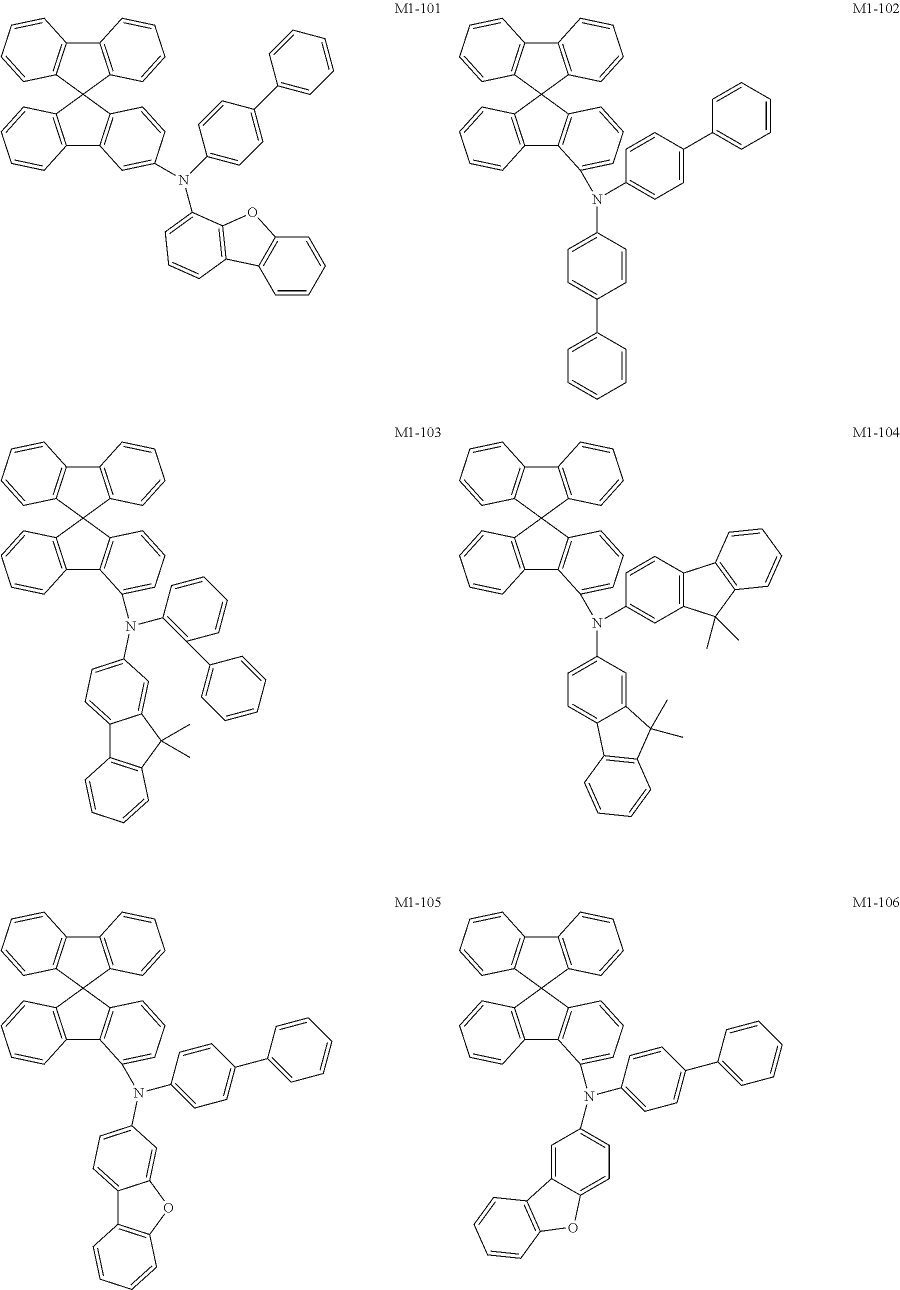

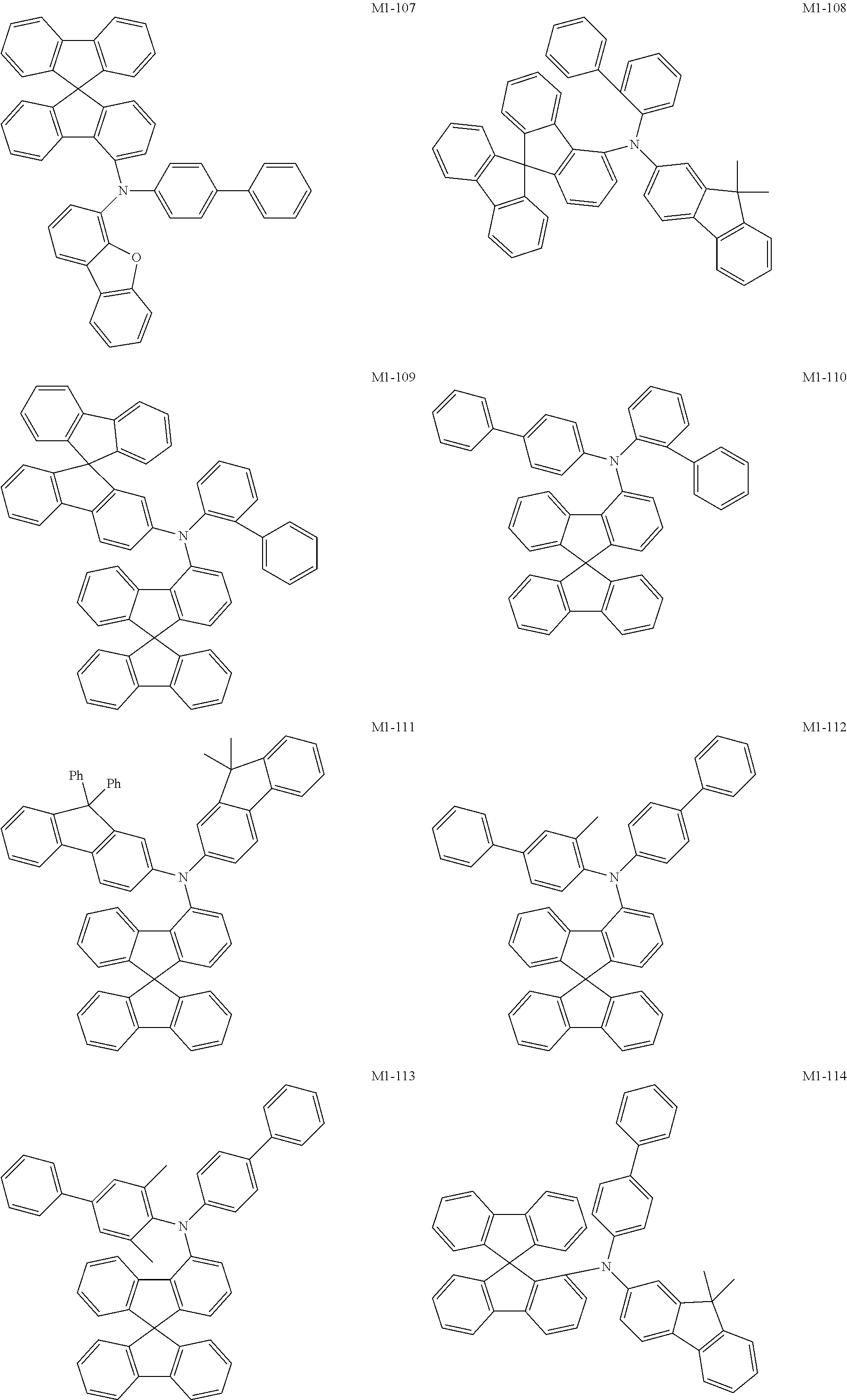

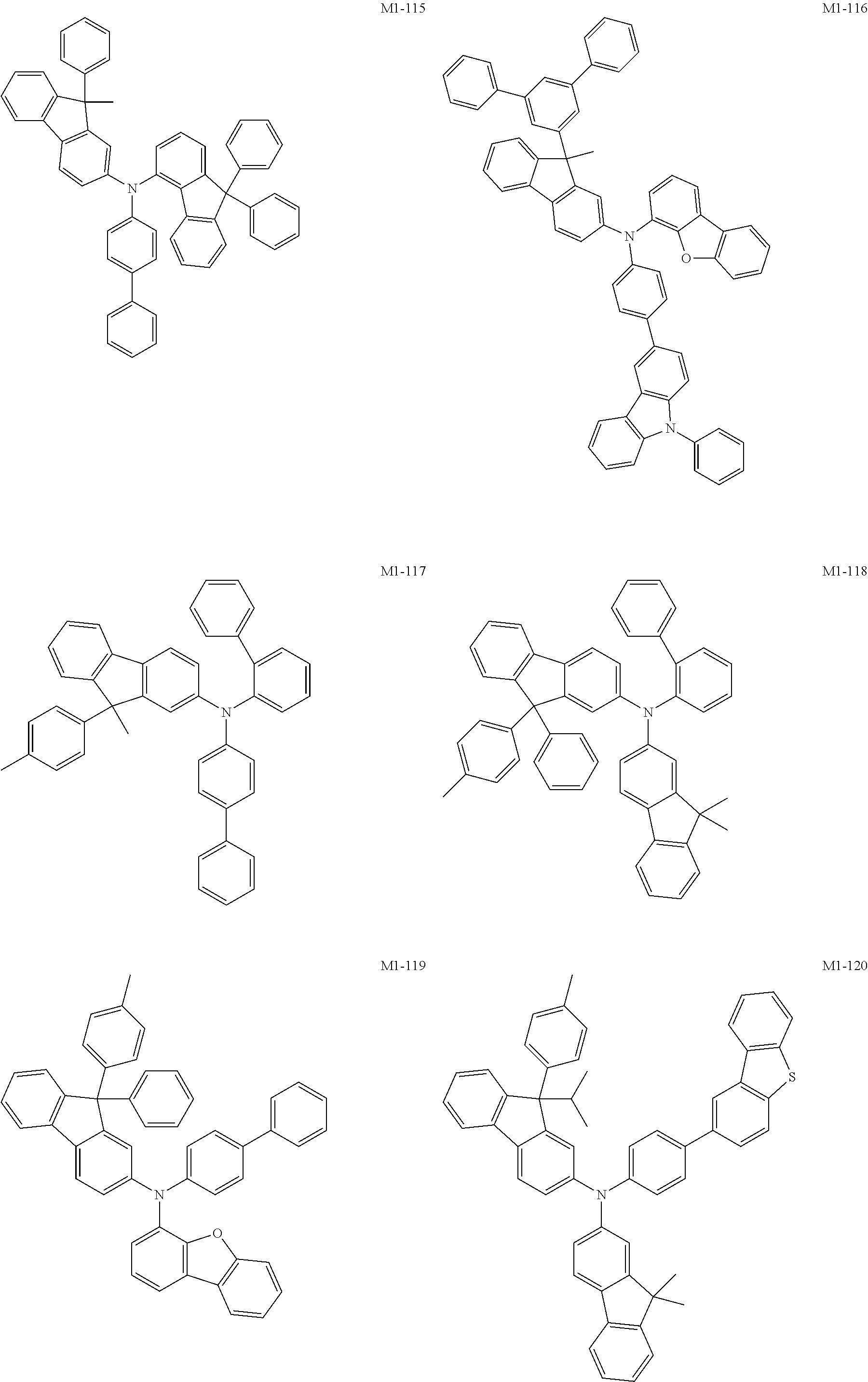

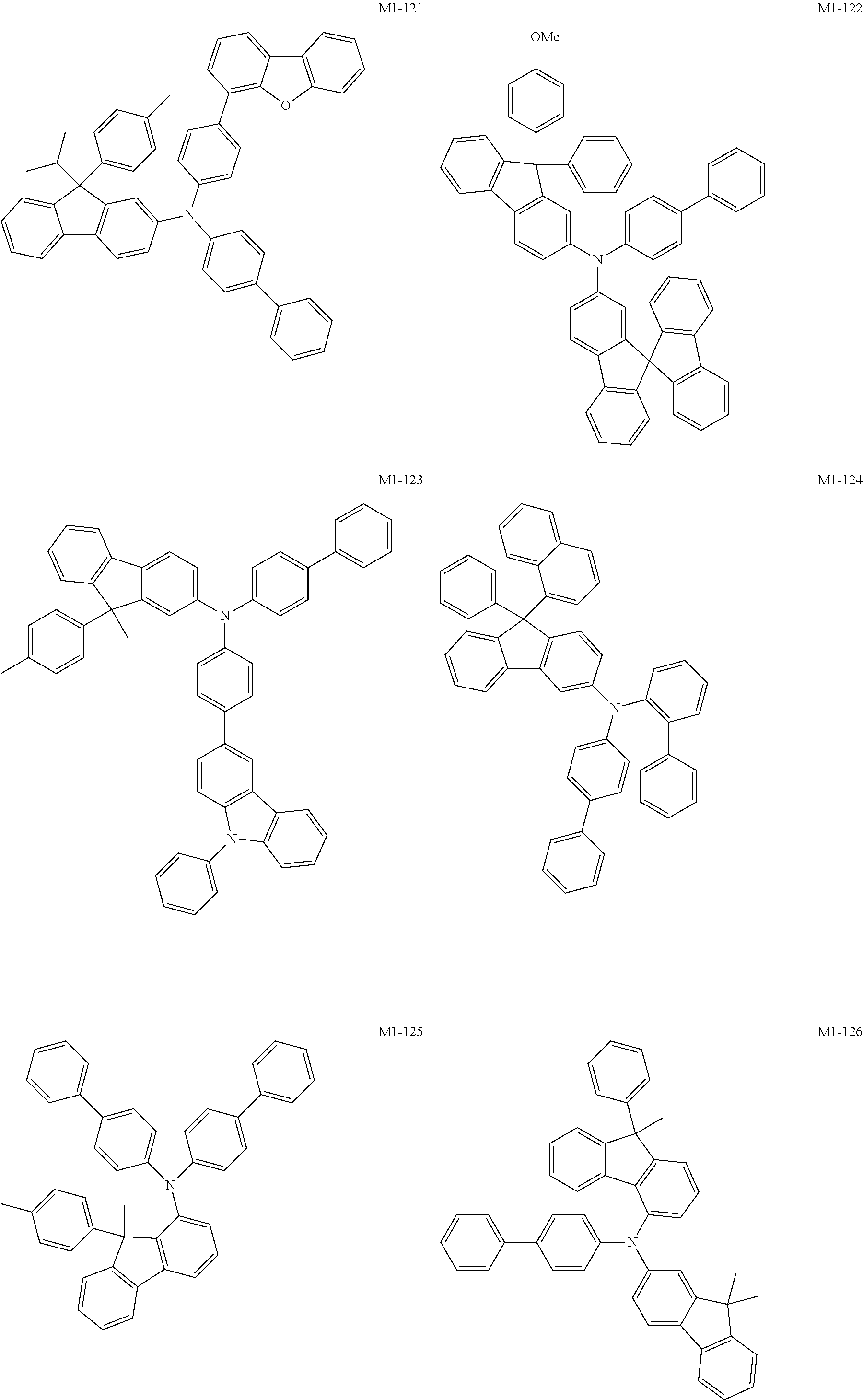

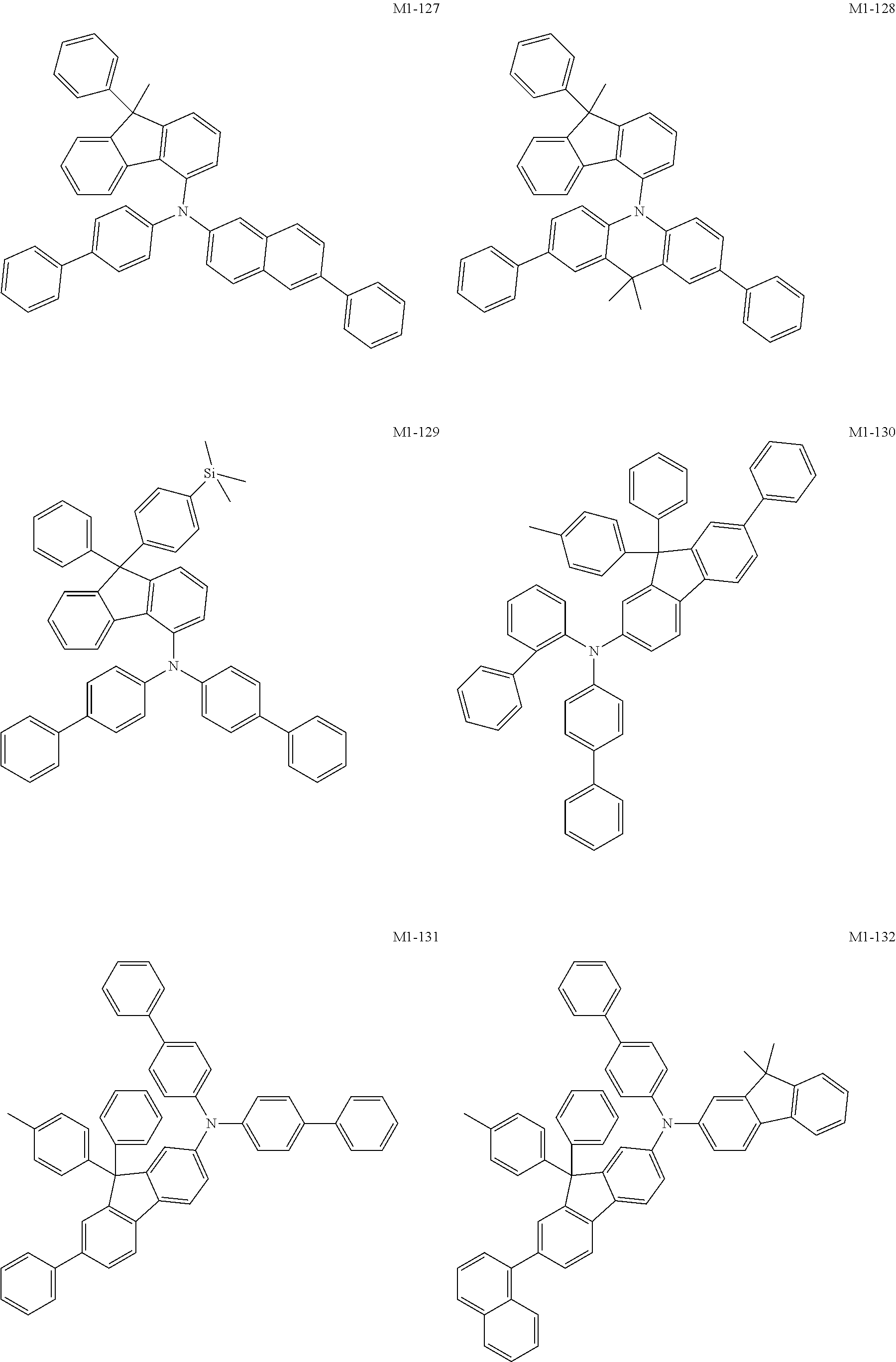

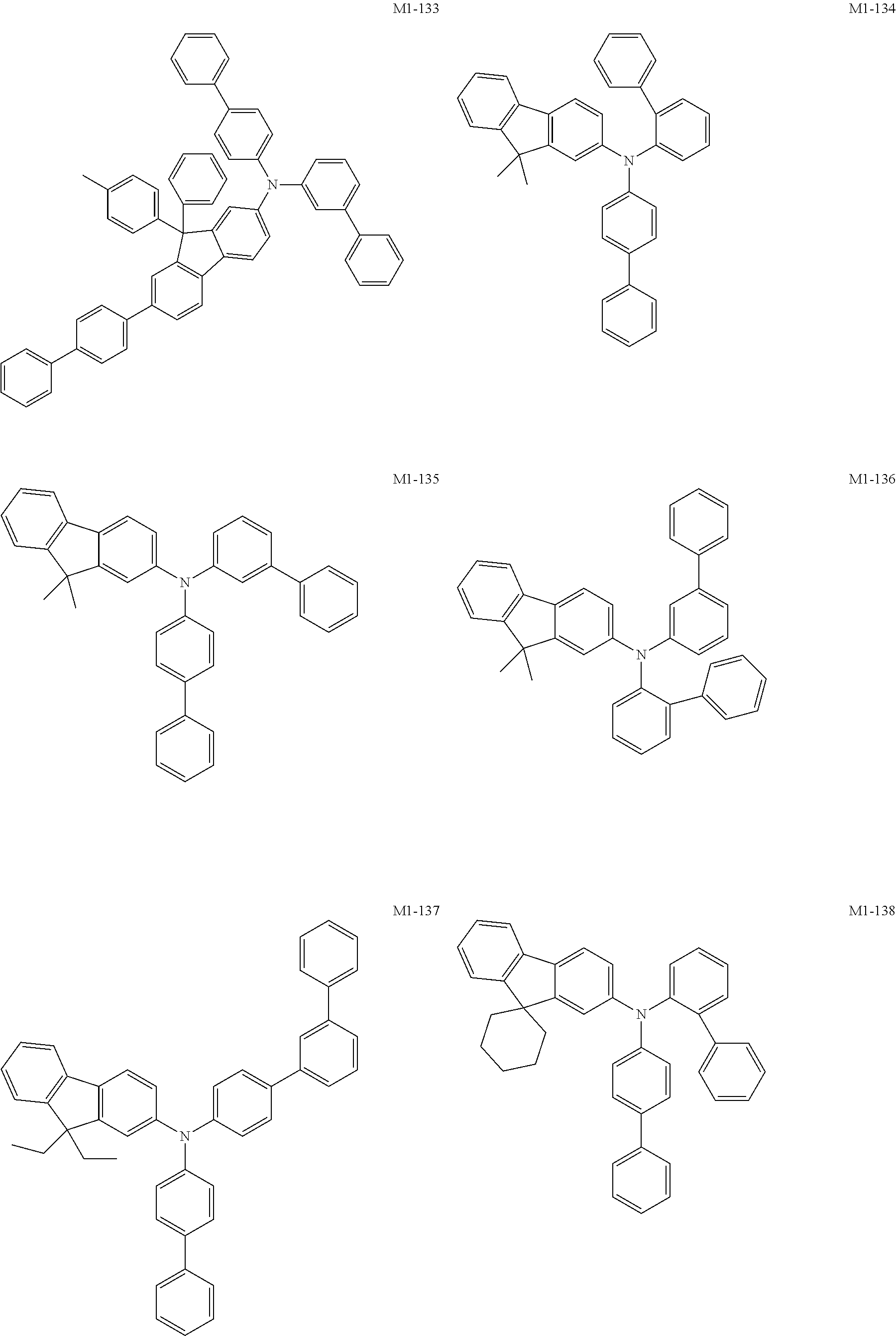 [SMILES: Cc1ccc(C2(c3ccccc3)c3cc(-c4ccc(-c5ccccc5)cc4)ccc3-c3ccc(N(c4ccc(-c5ccccc5)cc4)c4cccc(-c5ccccc5)c4)cc32)cc1 ; CC1(C)c2ccccc2-c2ccc(N(c3ccc(-c4ccccc4)cc3)c3ccccc3-c3ccccc3)cc21 ; CC1(C)c2ccccc2-c2ccc(N(c3ccc(-c4ccccc4)cc3)c3cccc(-c4ccccc4)c3)cc21 ; CC1(C)c2ccccc2-c2ccc(N(c3cccc(-c4ccccc4)c3)c3ccccc3-c3ccccc3)cc21 ; CCC1(CC)c2ccccc2-c2ccc(N(c3ccc(-c4ccccc4)cc3)c3ccc(-c4cccc(-c5ccccc5)c4)cc3)cc21 ; c1ccc(-c2ccc(N(c3ccc4c(c3)C3(CCCCC3)c3ccccc3-4)c3ccccc3-c3ccccc3)cc2)cc1]

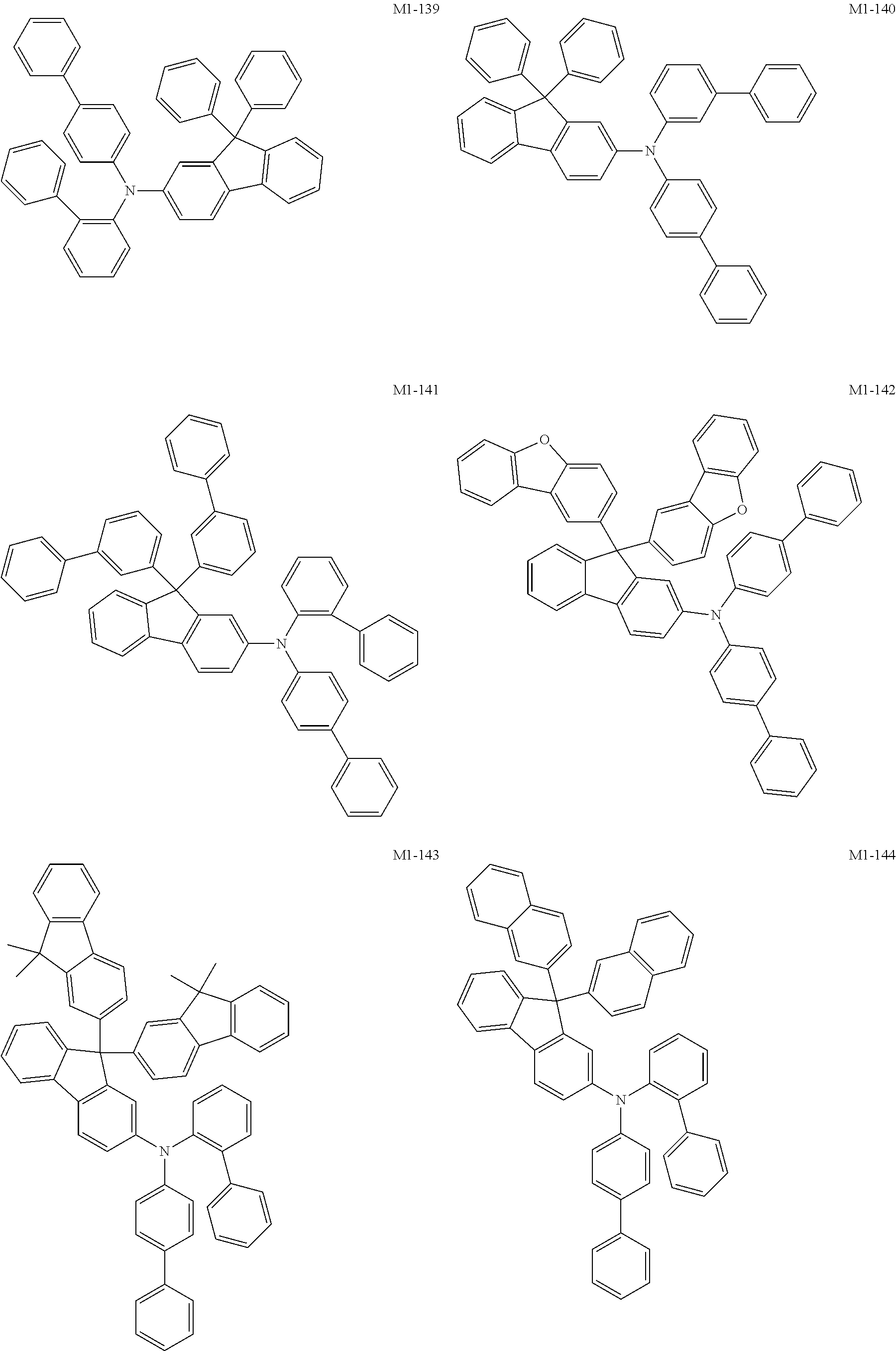

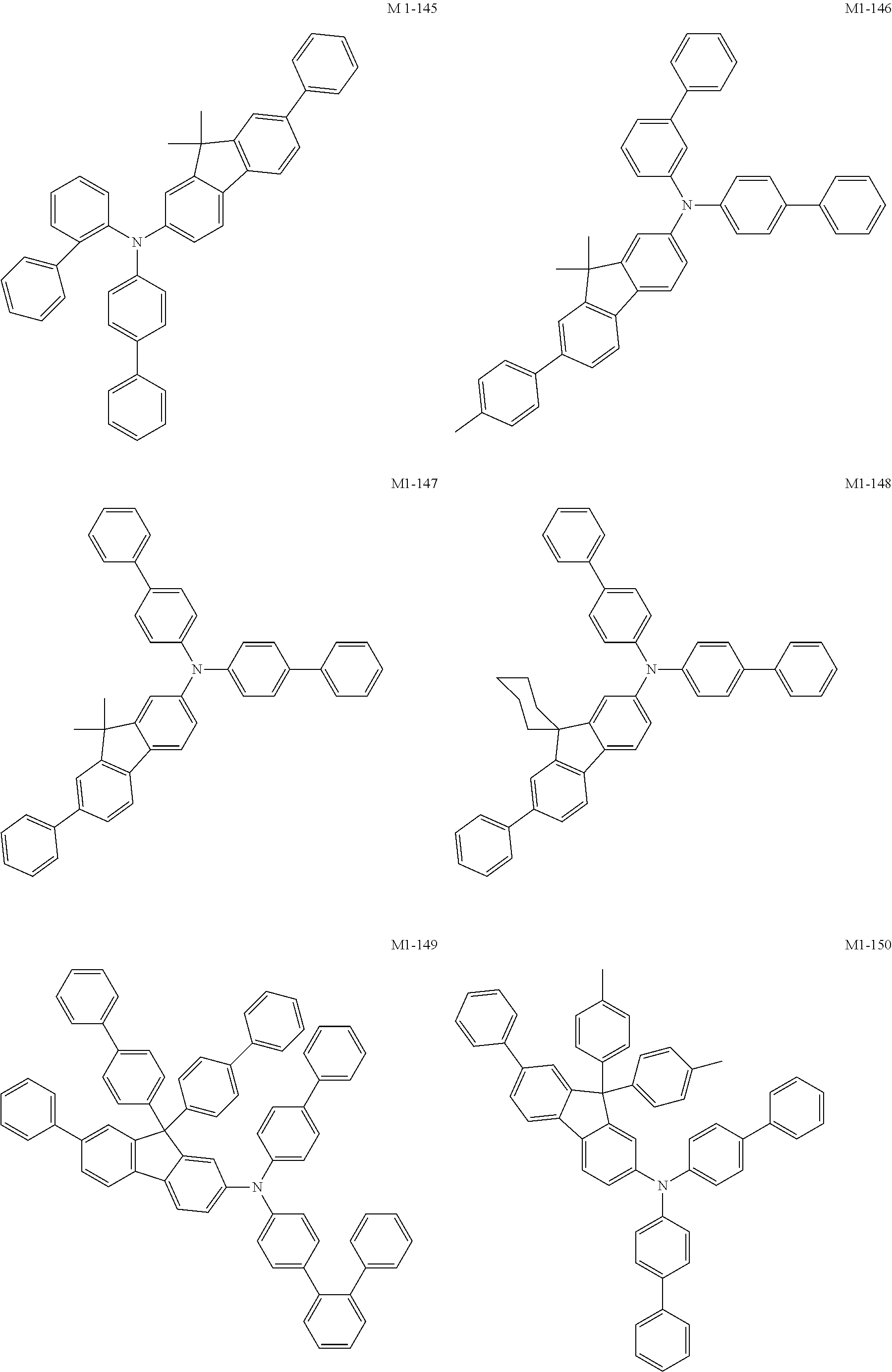

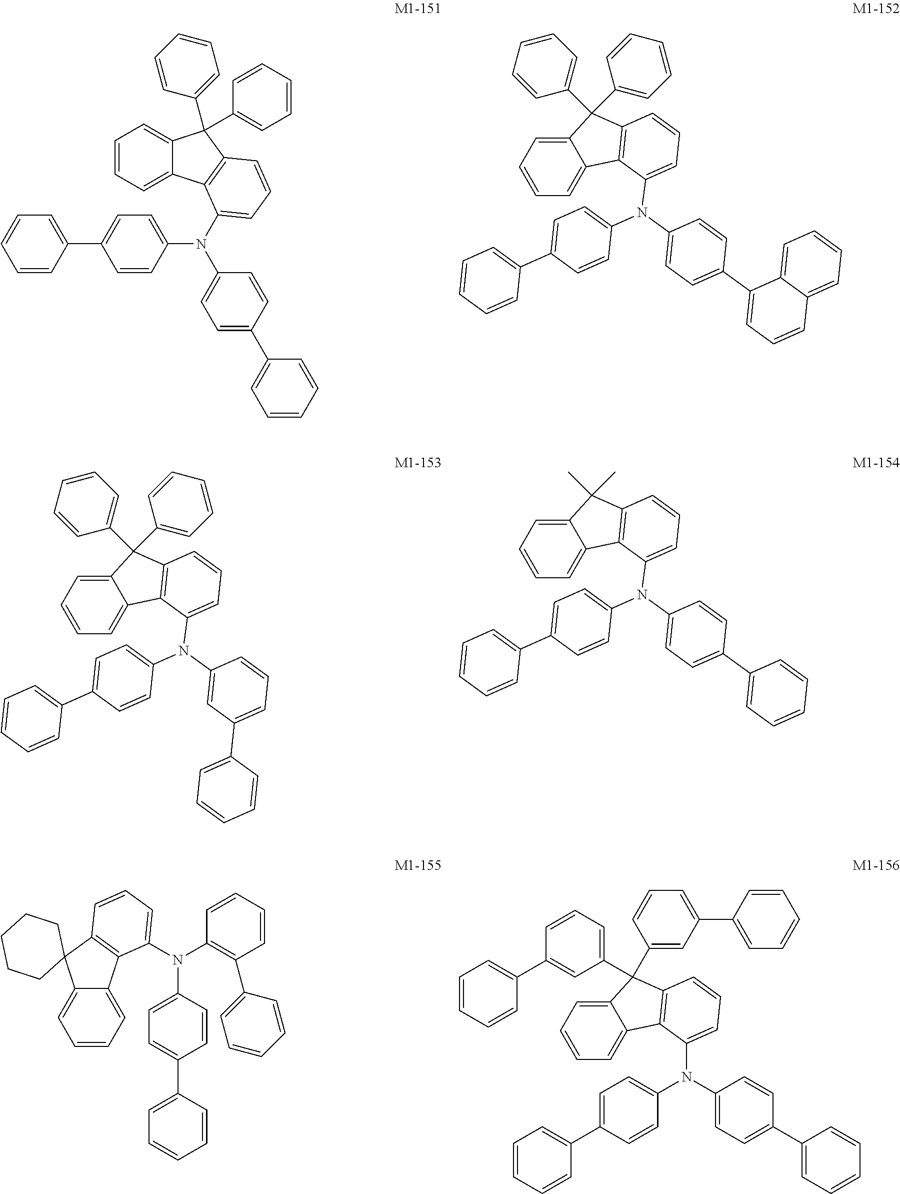

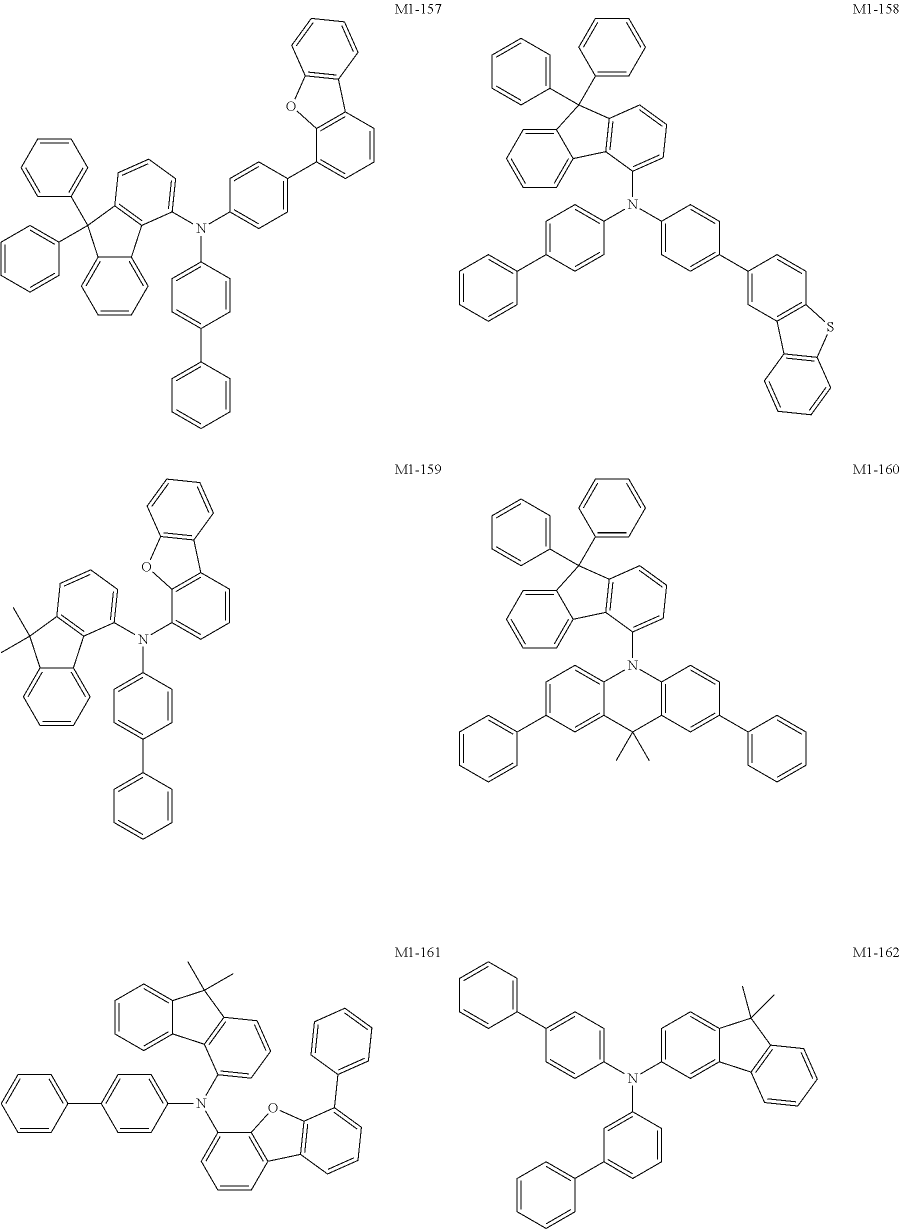 [SMILES: c1ccc(-c2ccc(N(c3ccc(-c4cccc5c4oc4ccccc45)cc3)c3cccc4c3-c3ccccc3C4(c3ccccc3)c3ccccc3)cc2)cc1 ; c1ccc(-c2ccc(N(c3ccc(-c4ccc5sc6ccccc6c5c4)cc3)c3cccc4c3-c3ccccc3C4(c3ccccc3)c3ccccc3)cc2)cc1 ; CC1(C)c2ccccc2-c2c(N(c3ccc(-c4ccccc4)cc3)c3cccc4c3oc3ccccc34)cccc21 ; CC1(C)c2cc(-c3ccccc3)ccc2N(c2cccc3c2-c2ccccc2C3(c2ccccc2)c2ccccc2)c2ccc(-c3ccccc3)cc21 ; CC1(C)c2ccccc2-c2c(N(c3ccc(-c4ccccc4)cc3)c3cccc4c3oc3c(-c5ccccc5)cccc34)cccc21 ; CC1(C)c2ccccc2-c2cc(N(c3ccc(-c4ccccc4)cc3)c3cccc(-c4ccccc4)c3)ccc21]

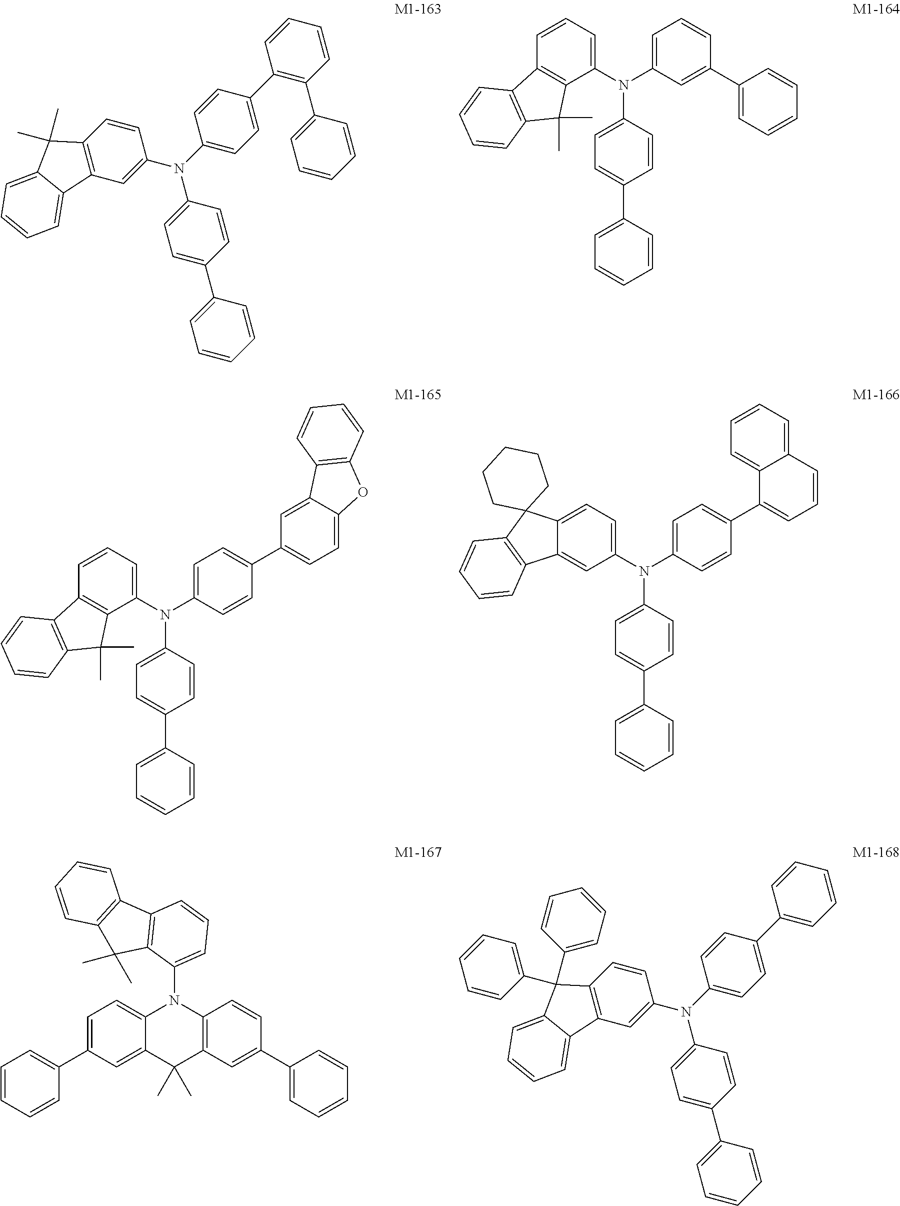 [SMILES: CC1(C)c2ccccc2-c2cc(N(c3ccc(-c4ccccc4)cc3)c3ccc(-c4ccccc4-c4ccccc4)cc3)ccc21 ; CC1(C)c2ccccc2-c2cccc(N(c3ccc(-c4ccccc4)cc3)c3cccc(-c4ccccc4)c3)c21 ; CC1(C)c2ccccc2-c2cccc(N(c3ccc(-c4ccccc4)cc3)c3ccc(-c4ccc5oc6ccccc6c5c4)cc3)c21 ; c1ccc(-c2ccc(N(c3ccc(-c4cccc5ccccc45)cc3)c3ccc4c(c3)-c3ccccc3C43CCCCC3)cc2)cc1 ; CC1(C)c2cc(-c3ccccc3)ccc2N(c2cccc3c2C(C)(C)c2ccccc2-3)c2ccc(-c3ccccc3)cc21 ; c1ccc(-c2ccc(N(c3ccc(-c4ccccc4)cc3)c3ccc4c(c3)-c3ccccc3C4(c3ccccc3)c3ccccc3)cc2)cc1]

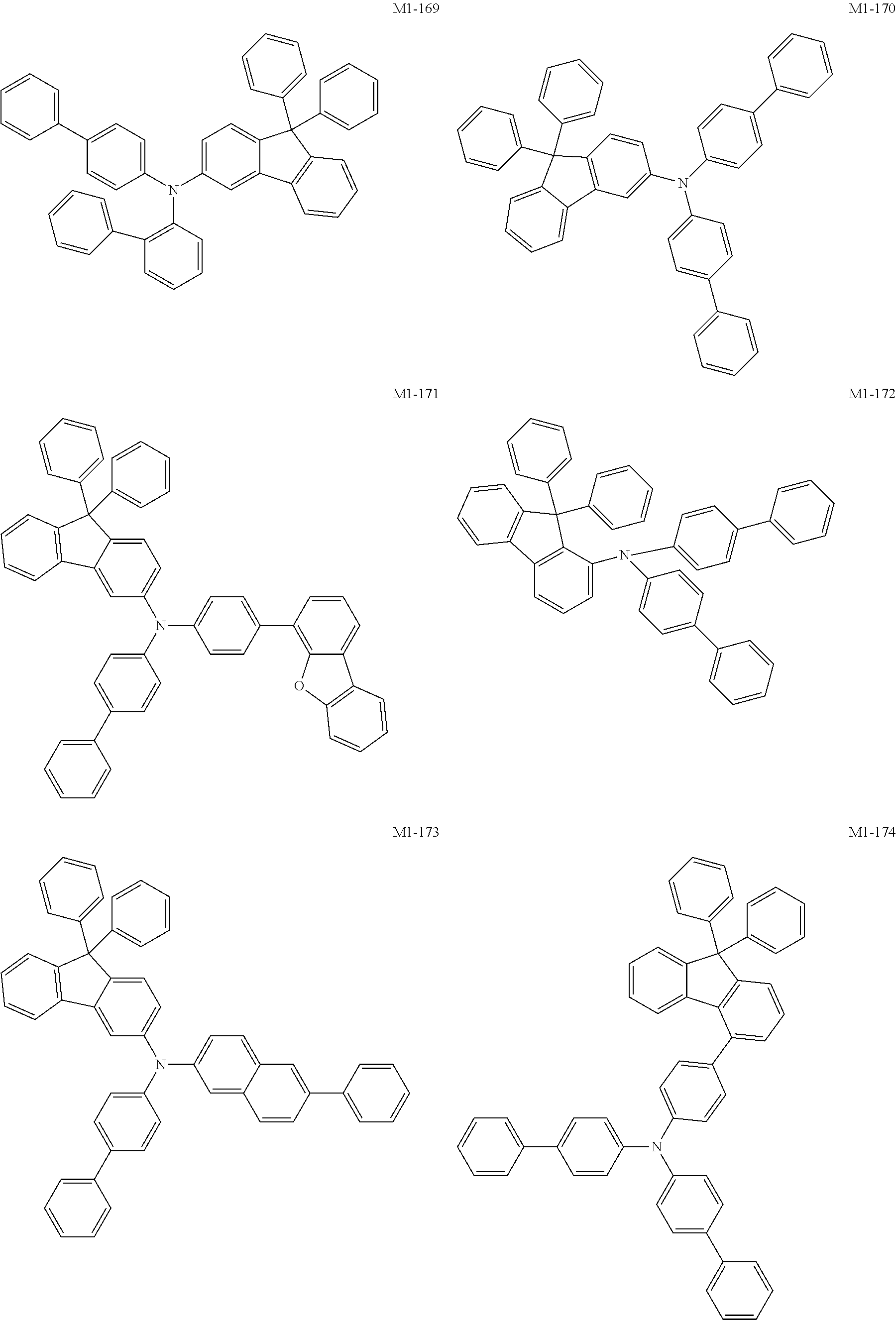

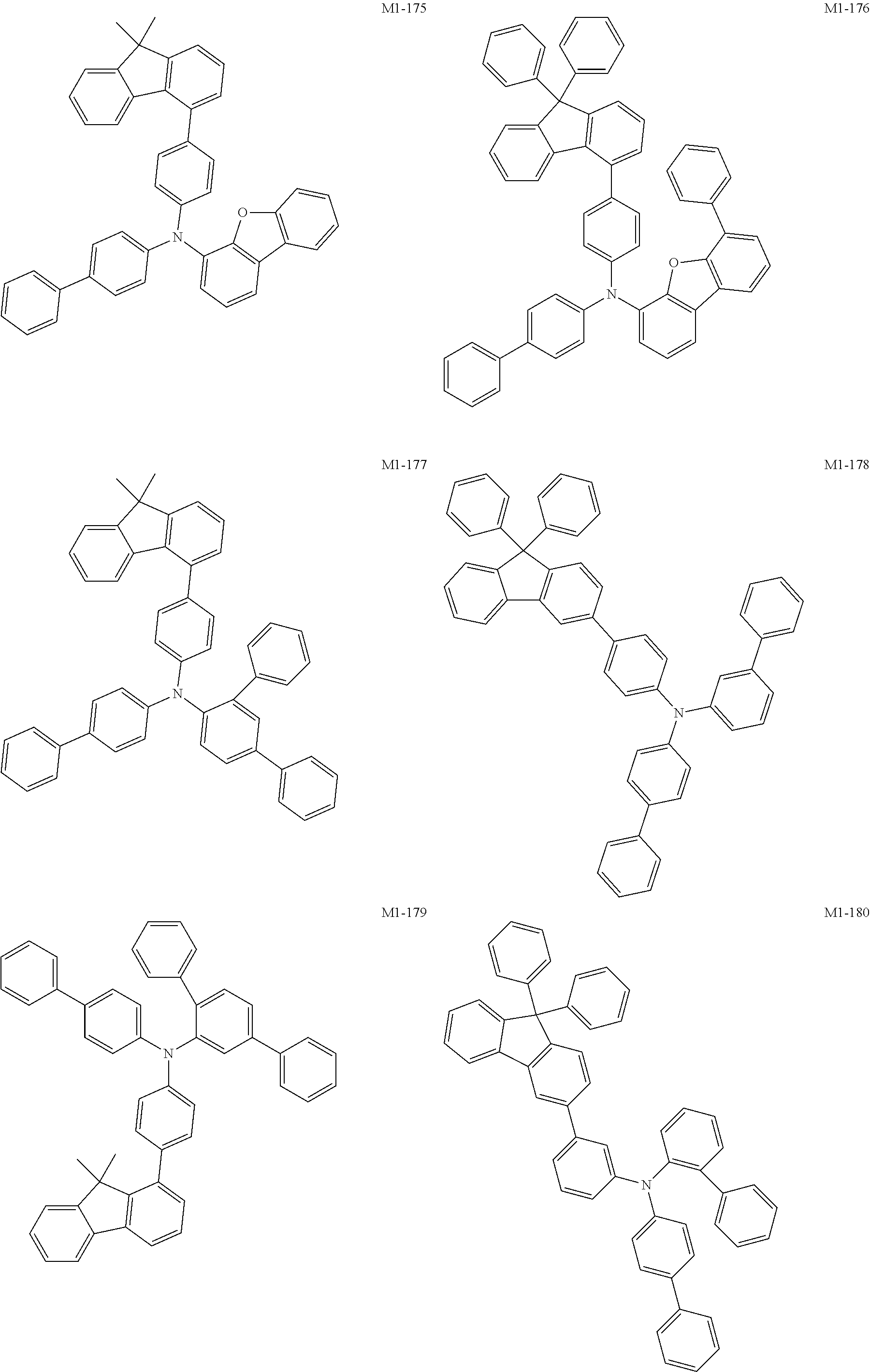

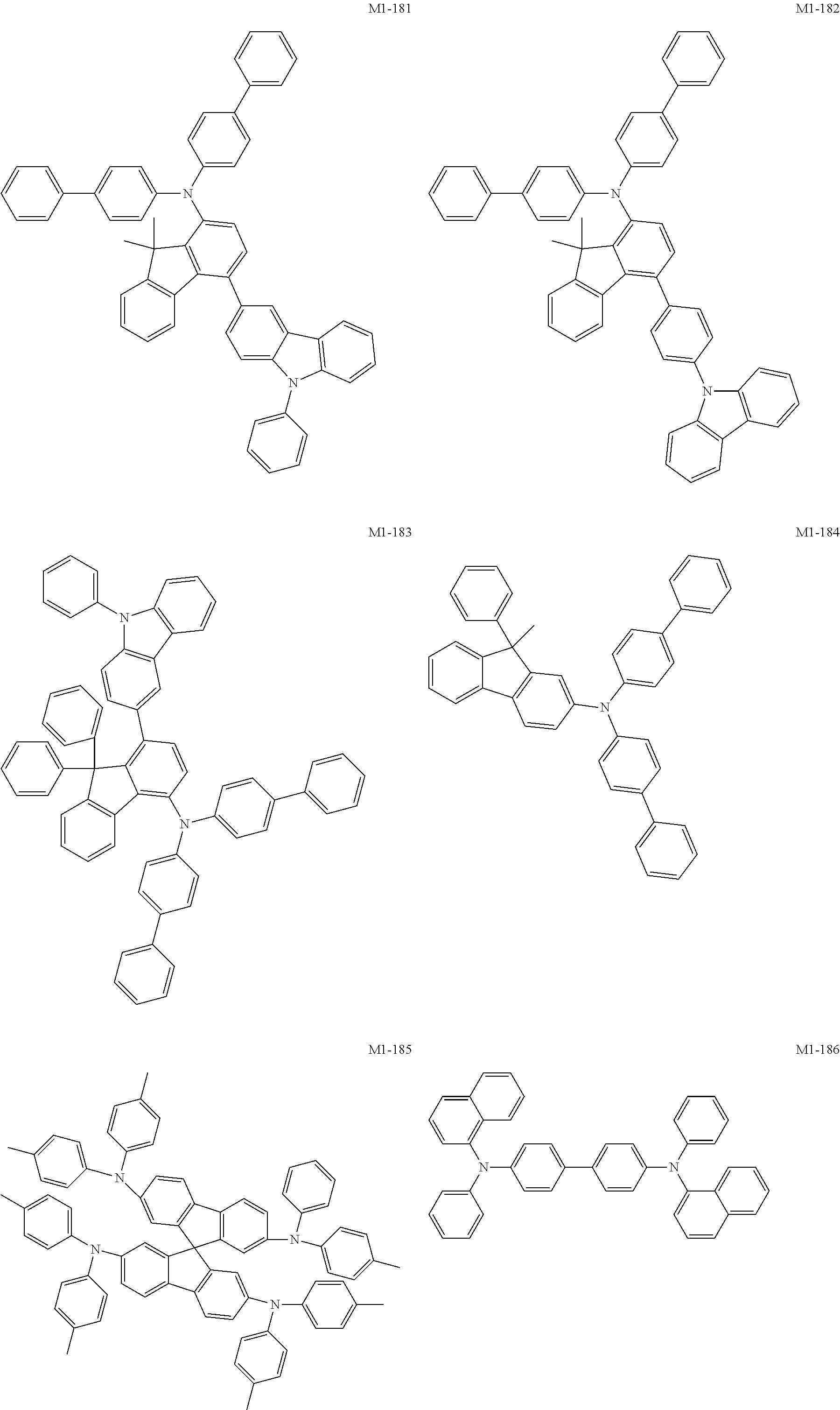

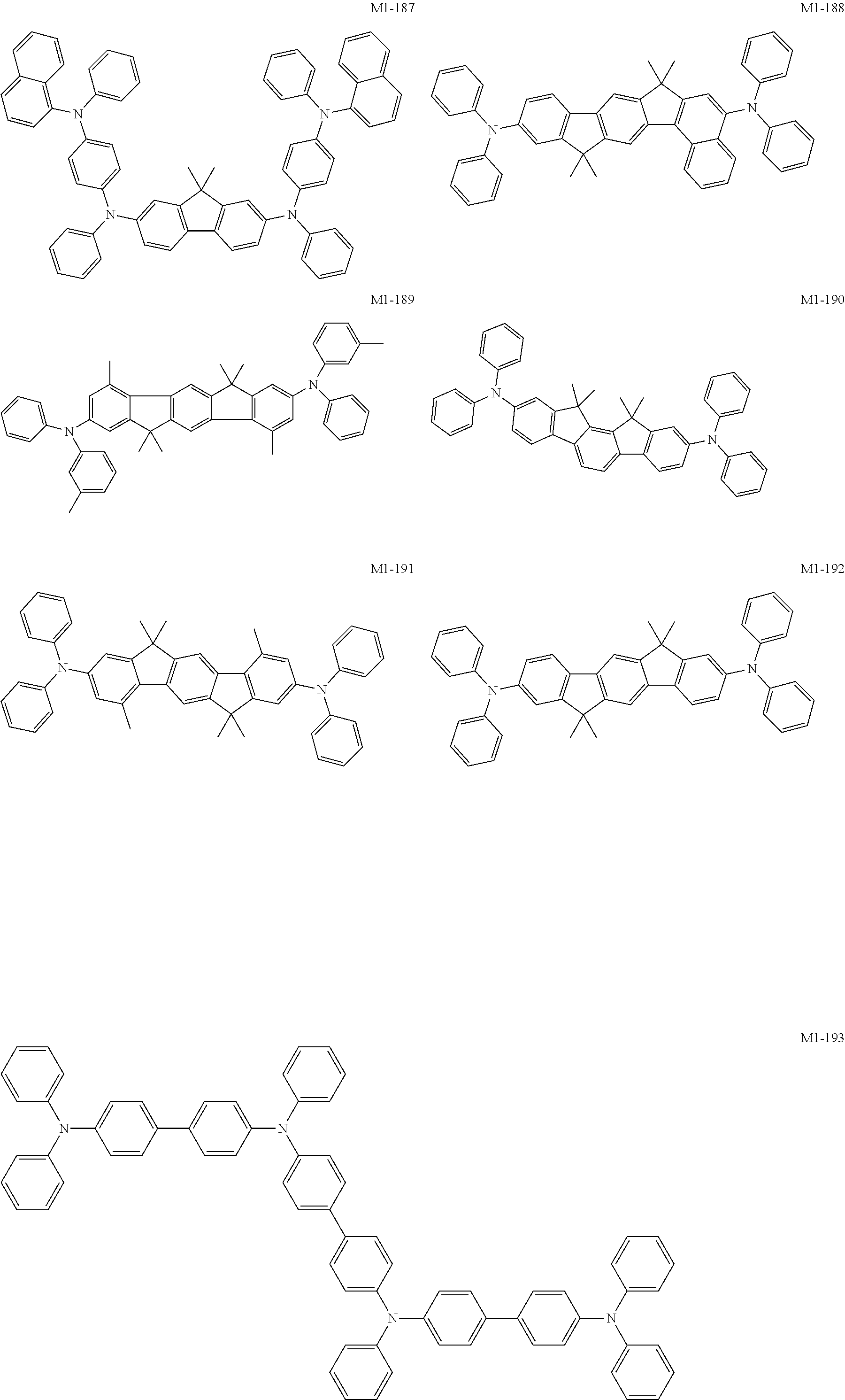

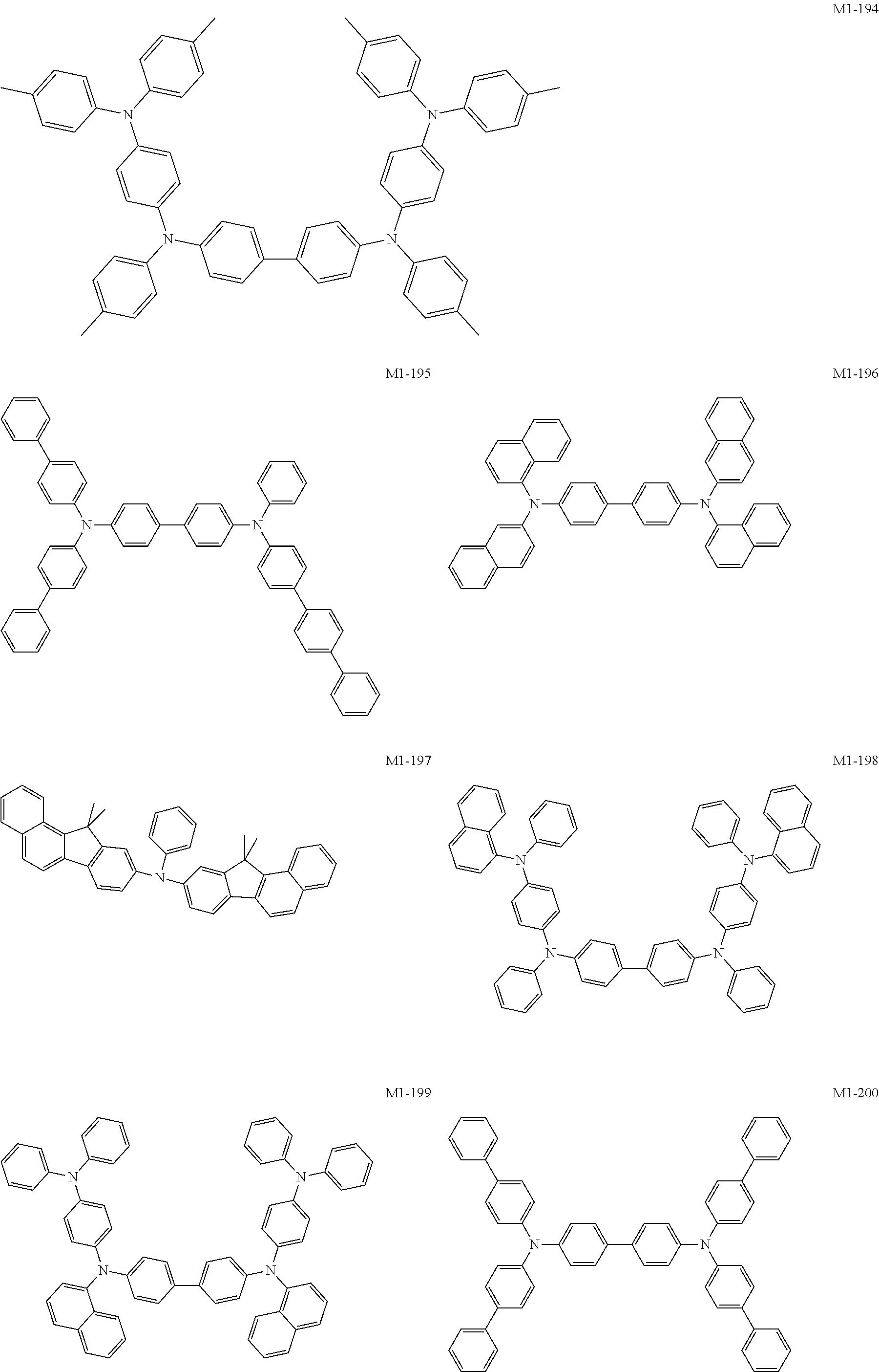

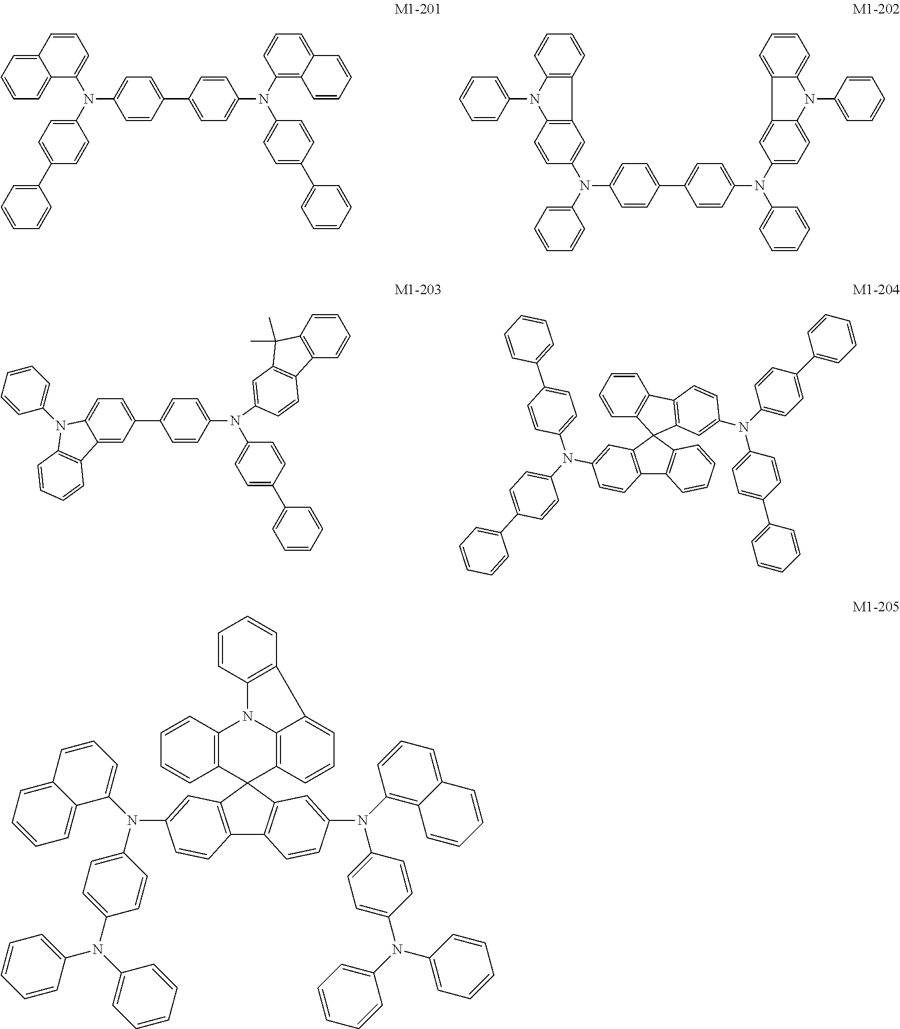

The HOMO of the matrix material M1 is preferably between 7.0 eV and −3.8 eV, preferably between −6.0 eV and −4.0 eV and particularly preferably between −5.5 eV and −5.0 eV.

According to a preferred embodiment of the invention, the matrix material M2 is a small organic molecule. It is preferably not a polymer, dendrimer or oligomer. It preferably has a molecular weight of 200 to 2000 g/mol, particularly preferably 250 to 1500 g/mol and very particularly preferably of 300 to 1000 g/mol.

The matrix material M2 is preferably a compound containing at least one anthracene unit. It is preferably a 9,10-diarylanthracene compound, which is optionally substituted by one or more radicals R⁵.

The matrix material M2 preferably conforms to the following formula (III)

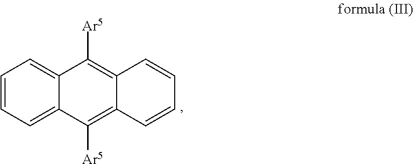

where:
Ar⁵ is on each occurrence, identically or differently, an aromatic or heteroaromatic ring system having 5 to 40 aromatic ring atoms, which may be substituted by one or more radicals R⁵; and
R⁵ is on each occurrence, identically or differently, H, D, F, C(═O)R⁶, CN, Si(R⁶)₃, N(R⁶)₂, P(═O)(R⁶)₂, S(═O)R⁶, S(═O)₂R⁶, a straight-chain alkyl or alkoxy group having 1 to 20 C atoms or a branched or cyclic alkyl or alkoxy group having 3 to 20 C atoms or an alkenyl or alkynyl group having 2 to 20 C atoms, where the above-mentioned groups may each be substituted by one or more radicals R⁶ and where one or more CH₂ groups in the above-mentioned groups may be replaced by —R⁶C═CR⁶—, —C≡C—, Si(R⁶)₂, C═O, C═S, C═NR, —C(═O)O—, —C(═O)NR⁶—, NR⁶, P(═O)(R⁶), —O—, —S—, SO or SO₂ and where one or more H atoms in the above-mentioned groups may be replaced by D, F or CN, or an aromatic or heteroaromatic ring system having 5 to 30 aromatic ring atoms, which may in each case be substituted by one or more radicals R⁶, or an aryloxy or heteroaryloxy group having 5 to 30 aromatic ring atoms, which may be substituted by one or more radicals R⁶, where two or more radicals R⁵ may be linked to one another and may form a ring;
R⁶ is on each occurrence, identically or differently, H, D, F or an aliphatic, aromatic or heteroaromatic organic radical having 1 to 20 C

atoms, in which, in addition, one or more H atoms may be replaced by D or F; two or more substituents R⁶ here may be linked to one another and may form a ring, and

the anthracene may be substituted at all free positions by a group R⁵.

Ar⁵ is preferably selected on each occurrence, identically or differently, from aryl groups having 6 to 18 aromatic ring atoms, preferably 6 to 14 aromatic ring atoms, which may be substituted by one or more radicals R⁵.

The matrix material M2 particularly preferably conforms to the formula (III-1)

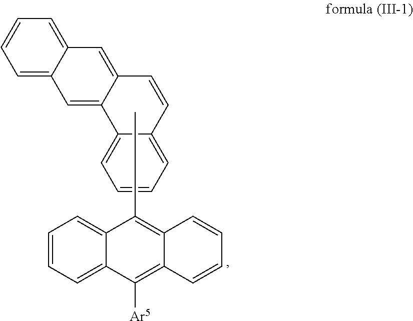

where Ar⁵ is as defined above and the benzanthracenyl group can be bonded to the anthracene in positions 1, 2, 3, 4, 5 or 6 and the benzanthracene and the anthracene may be substituted at all free positions by a group R⁵.

For the purposes of the application, the following numbering of the benzanthracene skeleton is used:

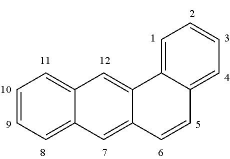 [SMILES: c1ccc2cc3c(ccc4ccccc43)cc2c1]

The matrix material M2 furthermore particularly preferably conforms to the following formula (III-2)

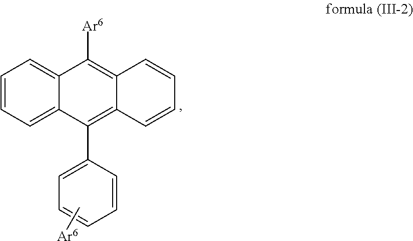

where
Ar⁶ is selected on each occurrence, identically or differently, from a condensed aryl or heteroaryl group having 10 to 18 aromatic ring atoms, which may be substituted by one or more radicals R⁵, and

the anthracene group and the phenylene group may be substituted at all free positions by a group R⁵.

Ar⁶ is preferably selected from naphthyl, anthracenyl, pyrenyl and fluoranthenyl groups, which may be substituted by one or more radicals R⁵.

Particularly preferred matrix materials M2 are the ansa-anthracenes disclosed in WO 2006/097208, the cycloalkylarylanthracenes disclosed in WO 2006/131192, the silyl-substituted anthracenes disclosed in WO 2007/065550, the tetraarylanthracenes disclosed in WO 2007/110129, the bis-anthracenes disclosed in WO 2007/065678, the benzanthracenes disclosed in WO 2008/145239, the phenanthrylanthracenes disclosed in WO 2009/100925, the 9,10-diarylanthracenes disclosed in WO 2011/054442, and the 9,10-diarylanthracenes disclosed in EP 1553154.

Examples of preferred matrix materials M2 for use in the electronic device according to the invention are depicted in the following table.

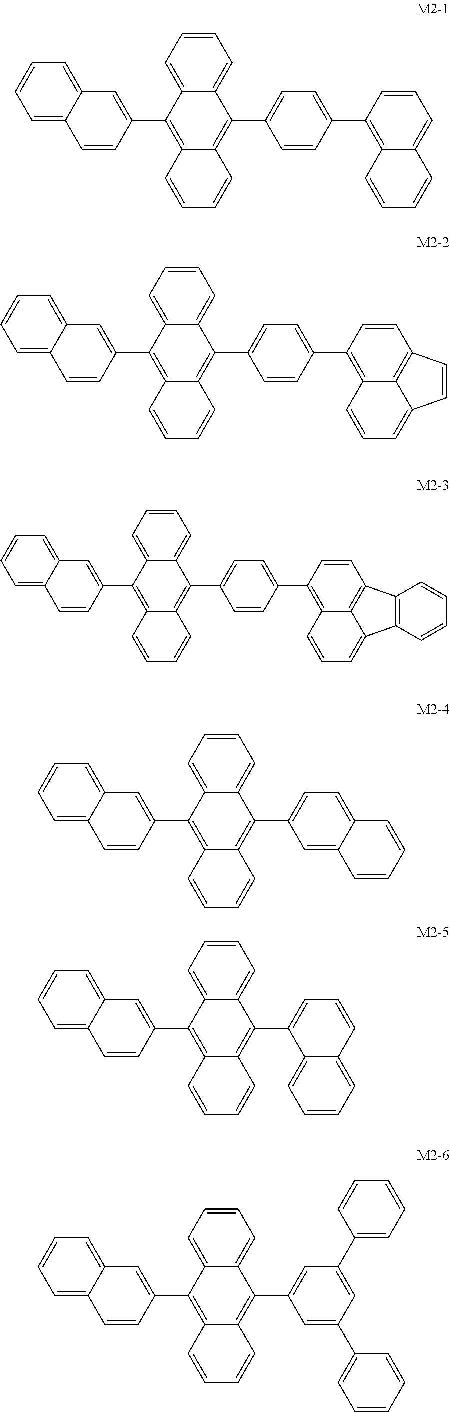

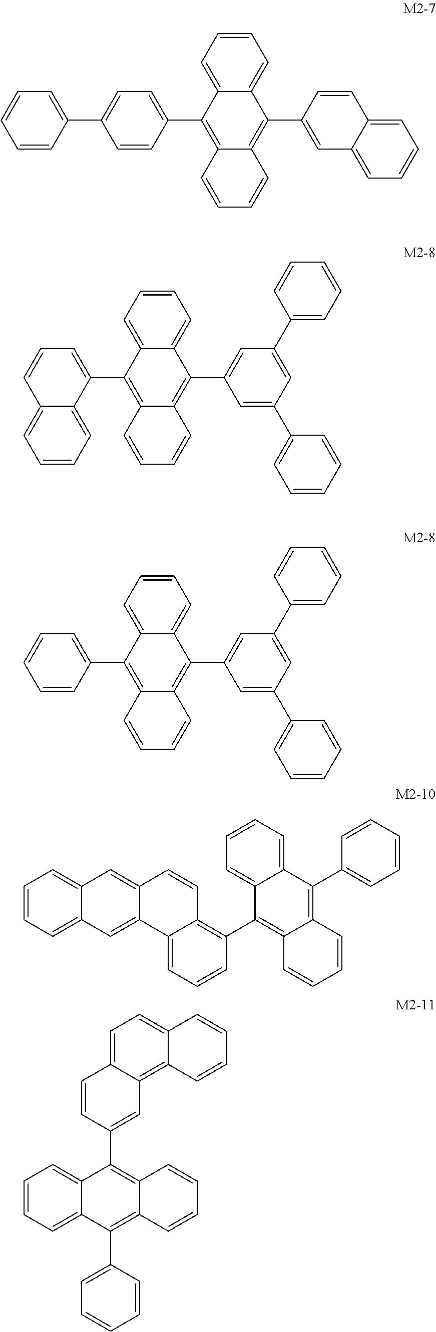

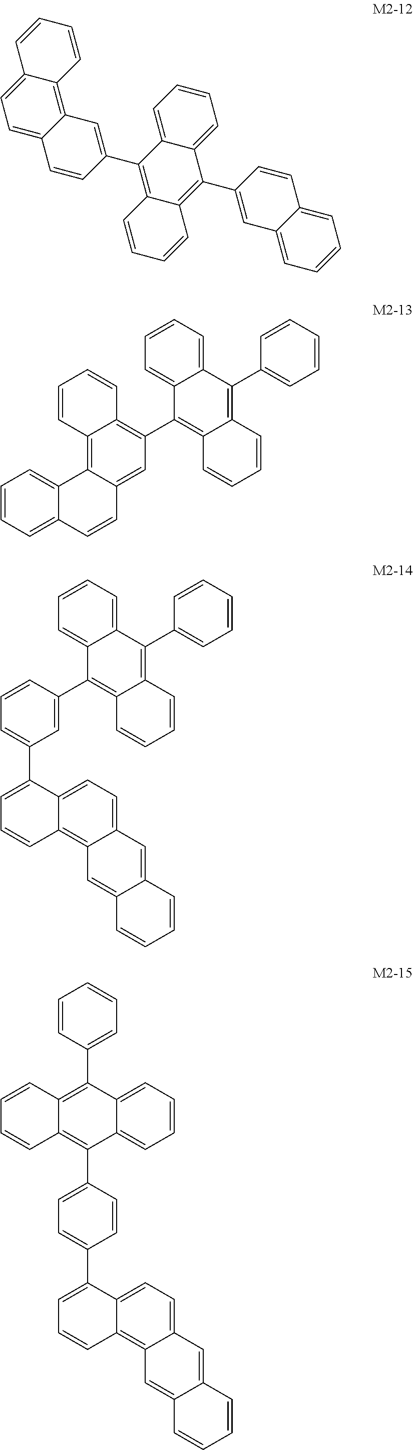

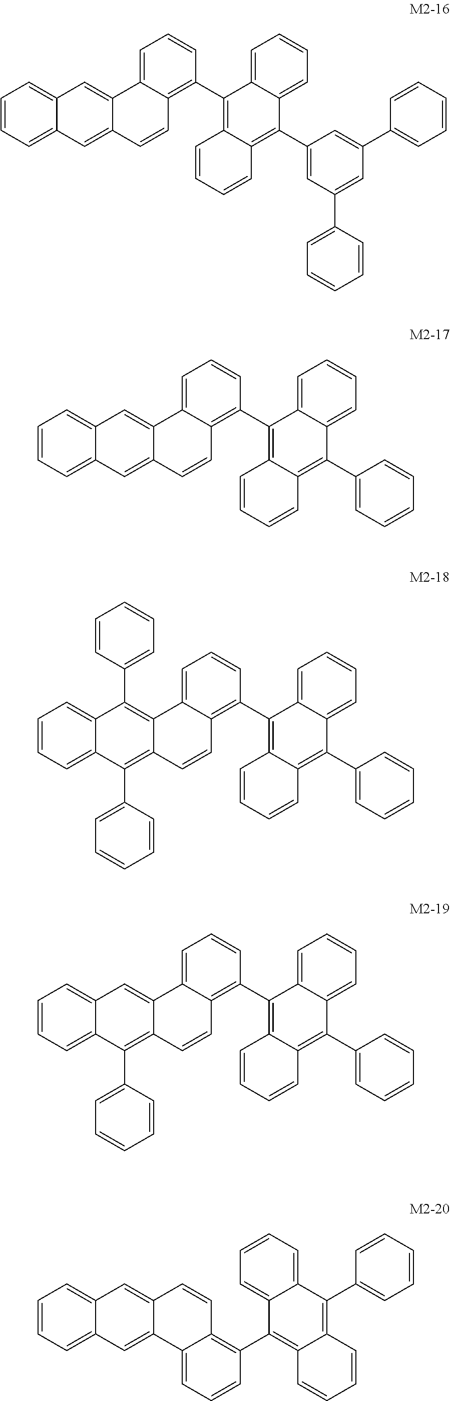

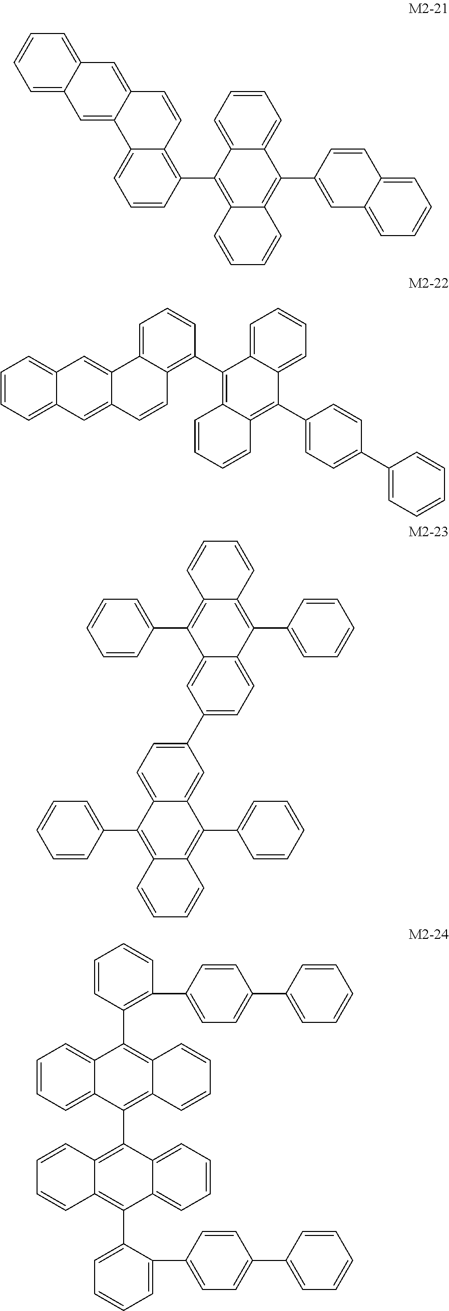

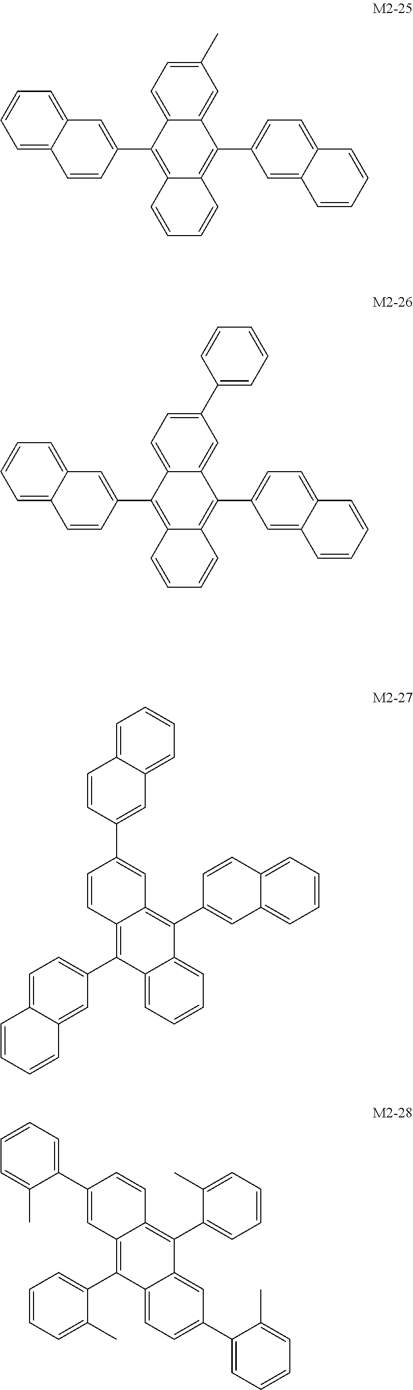

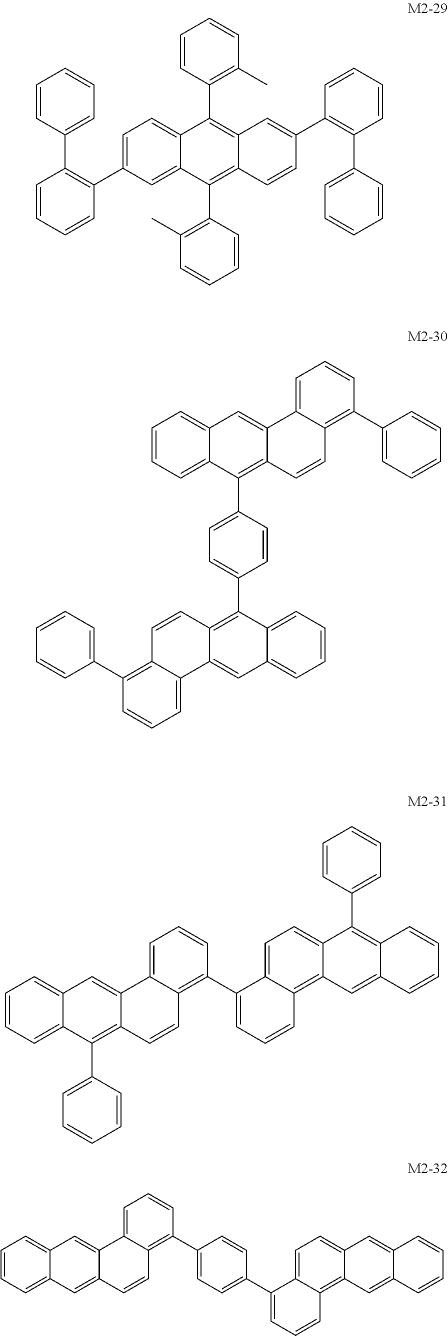

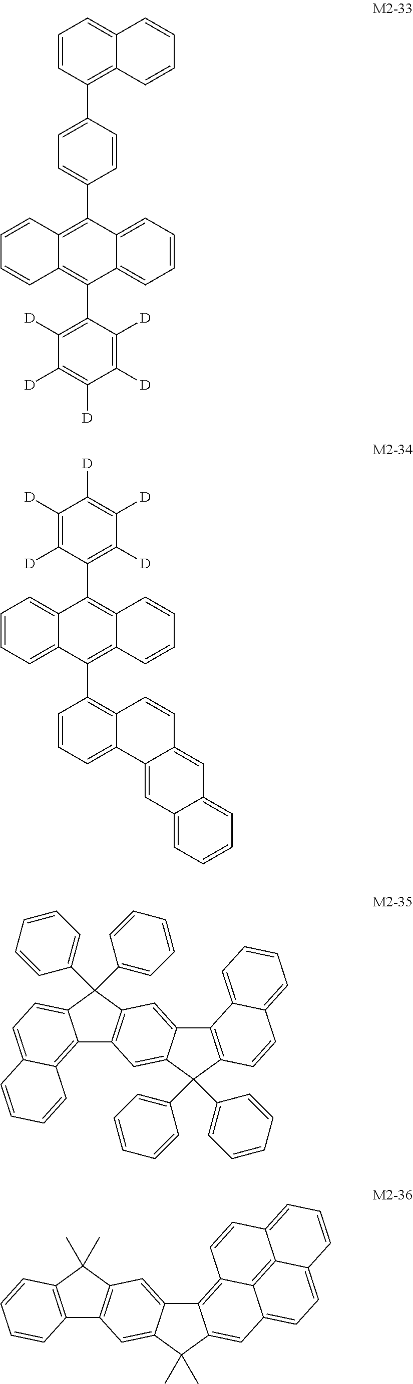

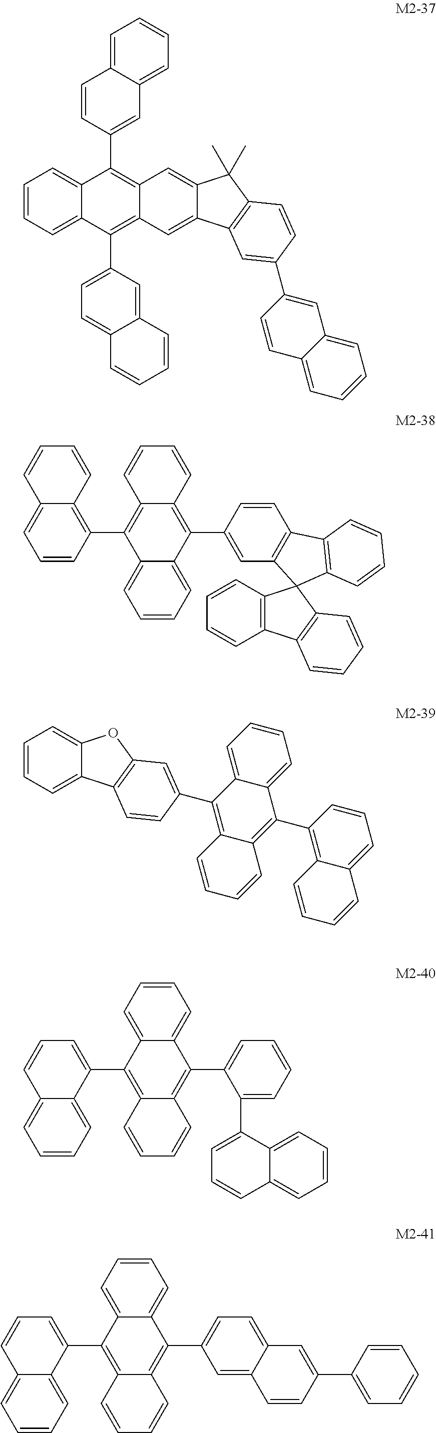

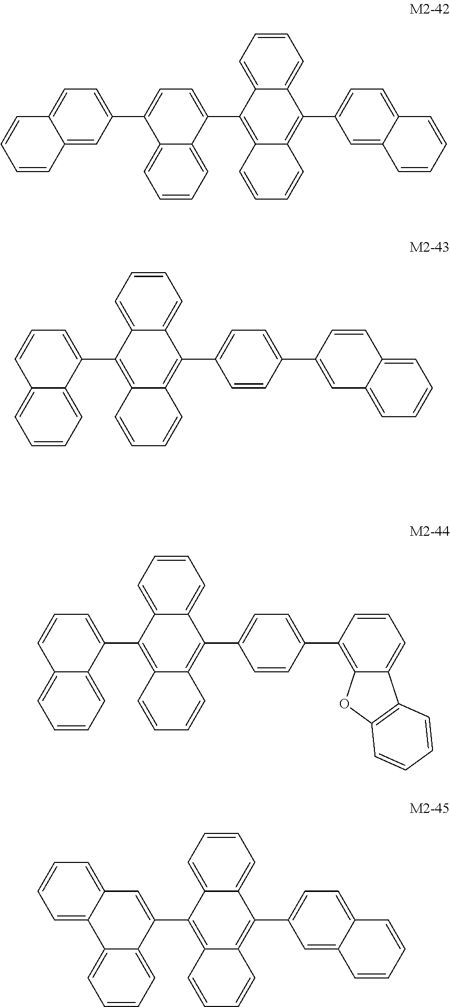

According to a preferred embodiment of the invention, the HOMO of the matrix material M2 is between −8.0 and −4.8 eV, particularly preferably between −6.5 and −5.0 eV, and very particularly preferably between −6.2 and −5.3 eV.

According to a preferred embodiment of the invention, the LUMO of the matrix material M2 is between −4.0 and −2.3 eV, particularly preferably between −3.0 and −2.5 eV and very particularly preferably between −2.9 and −2.6 eV.

In accordance with the invention, the following applies to the HOMOs of the compounds E, M1 and M2:

HOMO(M1)>HOMO(E)>HOMO(M2).

The separation between HOMO (M1) and HOMO (E) here is preferably greater than 0.05 eV, particularly preferably greater than 0.08 eV and very particularly preferably greater than 0.1 eV.

The separation between HOMO (E) and HOMO (M2) here is preferably greater than 0.05 eV, particularly preferably greater than 0.08 eV and very particularly preferably greater than 0.1 eV.

It is furthermore preferred in accordance with the invention for the LUMO of the matrix material M2 to have a lower value than the LUMO of the matrix material M1 and the LUMO of the emitter compound E.

The invention furthermore relates to a formulation comprising at least one organic solvent, at least one emitter compound E, at least one matrix material M1 and at least one matrix material M2, where the emitter compound E is selected from compounds containing at least one condensed aryl or heteroaryl group consisting of 2 to 4 aromatic rings condensed with one another,

where the matrix material M2 is selected from compounds containing at least one anthracene unit,

and where the following applies to the HOMOs of the compounds E, M1 and M2:

HOMO(M1)>HOMO(E)>HOMO(M2).

The compounds E, M1 and M2 are preferably selected differently in the formulation.

The formulation can be used in a process for the production of an electronic device. It is especially suitable for the production of the emitting layer of an electronic device, preferably of an OLED, by spin coating or by printing processes. The way in which such solutions can be prepared is known to the person skilled in the art and is described, for example, in WO 2002/072714, WO 2003/019694 and the literature cited therein.

Formulations can be, for example, solutions, dispersions or emulsions. It may be preferred to use mixtures of two or more solvents for this purpose.

Suitable and preferred solvents are, for example, toluene, anisole, o-, m- or p-xylene, methyl benzoate, mesitylene, tetralin, veratrol, THF, methyl-THF, THP, chlorobenzene, dioxane, phenoxytoluene, in particular 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol mono-butyl ether, tripropylene glycol dimethyl ether, tetraethylene glycol dimethyl ether, 2-isopropylnaphthalene, pentylbenzene, hexylbenzene, heptyl-benzene, octylbenzene, 1,1-bis(3,4-dimethylphenyl)ethane or mixtures of these solvents.

For the formulation according to the invention, the preferences indicated above relating to the proportions of the compounds E, M1 and M2 apply.

Furthermore, for the formulation according to the invention, the preferred embodiments indicated above for the compounds E, M1 and M2 apply.

In the electronic device according to the invention, the emitter compound E, the matrix material M1 and the matrix material M2 are preferably selected differently.

In accordance with the invention, the emitter compound E, the matrix material M1 and the matrix material M2 are present together in the emitting layer, preferably in a homogeneous mixture.

Besides the compounds E, M1 and M2, further compounds, for example further emitter compounds or further matrix materials, may be present in the emitting layer. Such compounds are preferably present in proportions of less than 10% by vol., particularly preferably less than 5% by vol. and very particularly preferably less than 3% by vol. According to a preferred embodiment, the electronic device according to the invention essentially comprises only the emitter compound E and the matrix materials M1 and M2 in the emitting layer. Further compound are in this case present at most in amounts of 1% by vol., preferably at most in amounts of 0.5% by vol. and particularly preferably at most in amounts of 0.1% by vol.

According to a preferred embodiment, the emitter compound E is present in the emitting layer in a proportion of 0.5-10% by vol., particularly preferably 1-8% by vol. and very particularly preferably 2-6% by vol.

According to a preferred embodiment, the matrix material M1 is present in the emitting layer in a proportion of 1-90% by vol., particularly preferably 3-60% by vol., and very particularly preferably 5-20% by vol.

According to a further preferred embodiment of the invention, the matrix material M1 is present in the emitting layer in a proportion of 7-16% by vol., particularly preferably in a proportion of 8-14% by vol. and very particularly preferably in a proportion of 9-12% by vol. This embodiment has the advantage that the performance data of the electronic device, in particular lifetime and efficiency, are thus improved compared with the use of smaller amounts of the matrix material M1.

The emitting layer of the electronic device according to the invention furthermore preferably emits light having an emission maximum at a wavelength of 430-480 nm, preferably 435-470 nm, particularly preferably 440-460 nm.

The emitting layer of the electronic device according to the invention furthermore preferably emits light having CIE coordinates of x<0.25 and y<0.35, preferably of x<0.2 and y<0.3. Furthermore preferably, x>0.1 and y>0.

The electronic device according to the invention is furthermore preferably selected from organic light-emitting transistors (OLETs), organic solar cells (OSCs), organic optical detectors, organic photoreceptors, organic field-quench devices (OFQDs), organic light-emitting electrochemical cells (OLECs), organic laser diodes (O-lasers) and organic electroluminescent devices (OLEDs). It is particularly preferably selected from organic electroluminescent devices.

According to a preferred embodiment of the invention, the electronic device, which is preferably selected from organic electroluminescent devices, has at least one further emitting layer in addition to an emitting layer which in accordance with the invention comprises the compounds E, M1 and M2.

According to a preferred embodiment of the invention, the electronic device, which is preferably selected from organic electroluminescent devices, has at least one hole-blocking layer, which is arranged on the cathode side in direct contact with the emitting layer. A hole-blocking layer here is taken to mean an electron-conducting layer which is located between emitting layer and cathode, and which has hole-blocking properties. It preferably has a low HOMO. It preferably additionally has a low LUMO.

According to a preferred embodiment of the invention, the electronic device, which is preferably selected from organic electroluminescent devices, has at least one electron-blocking layer, which is arranged on the anode side in direct contact with the emitting layer. An electron-blocking layer here is taken to mean a hole-conducting layer which is located between emitting layer and anode, and which has electron-blocking properties. It preferably has a high HOMO. It preferably additionally has a high LUMO.

Apart from cathode, anode and the emitting layer, the electronic device according to the invention may also comprise further layers. These are selected, for example, from in each case one or more hole-injection layers, hole-transport layers, hole-blocking layers, electron-transport layers, electron-injection layers, electron-blocking layers, exciton-blocking layers, interlayers, charge-generation layers (IDMC 2003, Taiwan; Session 21 OLED (5), T. Matsumoto, T. Nakada, J. Endo, K. Mori, N. Kawamura, A.

Yokoi, J. Kido, Multiphoton Organic EL Device Having Charge Generation Layer) and/or organic or inorganic p/n junctions. However, it should be pointed out that each of these layers does not necessarily have to be present.

The sequence of the layers of the electronic device is preferably the following:

anode/hole-injection layer/hole-transport layer/optionally additional hole-transport layers, preferably one, two or three additional hole-transport layers/emitting layer/electron-transport layer/electron-injection layer/cathode.

It should again be pointed out here that not all of the said layers have to be present, and/or that further layers may additionally be present. According to a preferred embodiment, precisely two additional hole-transport layers are present in the above-mentioned structure. According to a further preferred embodiment, one or more of the hole-transport layers comprise p-dopants. The p-dopants employed in this case are preferably compounds which are able to oxidise one or more of the other compounds of the hole-transport layer. The p-dopants are preferably organic electron-acceptor compounds.

Particularly preferred embodiments of p-dopants are the compounds disclosed in WO 2011/073149, EP 1968131, EP 2276085, EP 2213662, EP 1722602, EP 2045848, DE 102007031220, U.S. Pat. No. 8,044,390, U.S. Pat. No. 8,057,712, WO 2009/003455, WO 2010/094378, WO 2011/120709, US 2010/0096600 and WO 2012/095143.

The electronic device according to the invention can emit blue or white light or light of another colour, even if the emitting layer comprising the compounds E, M1 and M2 emits blue light. This can be achieved through the presence of further emitting layers and/or layers which convert the colour of the emitted light.

The electronic device according to the invention may comprise one or more further emitting layers. The emitting layers in this case particularly preferably have in total a plurality of emission maxima between 380 nm and 750 nm, resulting overall in white emission, i.e. various emitting compounds which are able to fluoresce or phosphoresce and emit blue or yellow or orange or red light are used in the emitting layers. Preference is given to three-layer systems, i.e. systems having three emitting layers, where the three layers exhibit blue, green and orange or red emission, or two-layer systems, where the two layers exhibit blue and orange emission (for the basic structure see, for example, WO 2005/011013). According to a preferred embodiment, the blue-emitting layer here is a fluorescent layer and the red-, orange-, green- or yellow-emitting layer(s) are phosphorescent layers.

For the purposes of the present application, fluorescence is taken to mean emission from a transition from an excited singlet state. Phosphorescence is taken to mean emission from a spin-forbidden transition, for example a transition from an excited triplet state or a state having a higher spin quantum number, for example a quintet state.

A fluorescent layer here is taken to mean a layer comprising a fluorescent emitter. Correspondingly, a phosphorescent layer is taken to mean a layer comprising a phosphorescent emitter.

Suitable phosphorescent emitters are, in particular, compounds which emit light, preferably in the visible region, on suitable excitation and in addition contain at least one atom having an atomic number greater than 20, preferably greater than 38 and less than 84, particularly preferably greater than 56 and less than 80. The phosphorescent dopants used are preferably compounds which contain copper, molybdenum, tungsten, rhenium, ruthenium, osmium, rhodium, iridium, palladium, platinum, silver, gold or europium, in particular compounds which contain iridium, platinum or copper.

For the purposes of the present invention, all luminescent iridium, platinum or copper complexes are regarded as phosphorescent compounds. Examples of the phosphorescent emitters described above are revealed by the applications WO 2000/70655, WO 2001/41512, WO 2002/02714, WO 2002/15645, EP 1191613, EP 1191612, EP 1191614, WO 2005/033244, WO 2005/019373 and US 2005/0258742.

Examples of fluorescent emitters are the compounds indicated above as preferred embodiments of the emitter compound E.

Suitable charge-transport materials, as can be used in the hole-injection or hole-transport layer or electron-blocking layer or in the electron-transport layer of the electronic device according to the invention, are, for example, the compounds disclosed in Y. Shirota et al., Chem. Rev. 2007, 107(4), 953-1010 or other materials as are employed in accordance with the prior art in these layers.

Materials which can be used for the electron-transport layer are all materials as are used in accordance with the prior art as electron-transport materials in the electron-transport layer. Particularly suitable are aluminium complexes, for example AIq3, zirconium complexes, for example Zrq4, benzimidazole derivatives, triazine derivatives, pyrimidine derivatives, pyri-dine derivatives, pyrazine derivatives, quinoxaline derivatives, quinoline derivatives, oxadiazole derivatives, aromatic ketones, lactams, boranes, diazaphosphole derivatives and phosphine oxide derivatives. Furthermore suitable materials are derivatives of the above-mentioned compounds, as disclosed in JP 2000/053957, WO 2003/060956, WO 2004/028217, WO 2004/080975 and WO 2010/072300.

Preferred hole-transport materials which can be used in a hole-transport, hole-injection or electron-blocking layer in the electroluminescent device according to the invention are indenofluorenamine derivatives (for example in accordance with WO 06/122630 or WO 06/100896), the amine derivatives disclosed in EP 1661888, hexaazatriphenylene derivatives (for example in accordance with WO 01/049806), amine derivatives containing condensed aromatic rings (for example in accordance with U.S. Pat. No. 5,061,569), the amine derivatives disclosed in WO 95/09147, monobenzoindenofluoren-amines (for example in accordance with WO 08/006449), dibenzoindeno-fluorenamines (for example in accordance with WO 07/140847), spiro-bifluorenamines (for example in accordance with WO 2012/034627 or WO 2013/120577), fluorenamines (for example in accordance with the as yet unpublished applications EP 12005369.9, EP 12005370.7 and EP 12005371.5), spirodibenzopyranamines (for example in accordance with WO 2013/083216) and dihydroacridine derivatives (for example in accordance with WO 2012/150001).

The cathode of the electronic device preferably comprises metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). Also suitable are alloys comprising an alkali metal or alkaline-earth metal and silver, for example an alloy comprising magnesium and silver. In the case of multilayered structures, further metals which have a relatively high work function, such as, for example, Ag or Al, can also be used in addition to the said metals, in which case combinations of the metals, such as, for example, Ca/Ag, Mg/Ag or Ba/Ag, are generally used. It may also be preferred to introduce a thin interlayer of a material having a high dielectric constant between a metallic cathode and the organic semiconductor. Suitable for this purpose are, for example, alkali metal fluorides or alkaline-earth metal fluorides, but also the corresponding oxides or carbonates (for example LiF, Li₂O, BaF₂, MgO, NaF, CsF, Cs₂CO₃, etc.). Furthermore, lithium quinolinate (LiQ) can be used for this purpose. The layer thickness of this layer is preferably between 0.5 and 5 nm.

The anode preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. For some applications, at least one of the electrodes must be transparent or partially transparent in order to facilitate either irradiation of the organic material (organic solar cells) or the coupling-out of light (OLEDs, O-lasers). Preferred anode materials here are conductive mixed metal oxides. Particular preference is given to indium tin oxide (ITO) or indium zinc oxide (IZO). Preference is furthermore given to conductive, doped organic materials, in particular conductive doped polymers. Furthermore, the anode may also consist of a plurality of layers, for example of an inner layer of ITO and an outer layer of a metal oxide, preferably tungsten oxide, molybdenum oxide or vanadium oxide.

The electronic device is appropriately (depending on the application) structured, provided with contacts and finally sealed, since the lifetime of the devices according to the invention is shortened in the presence of water and/or air.

In a preferred embodiment, the electronic device is characterised in that one or more layers are coated by means of a sublimation process, in which the materials are applied by vapour deposition in vacuum sublimation units at an initial pressure of less than 10⁻⁵ mbar, preferably less than 10⁻⁶ mbar.

However, it is also possible here for the initial pressure to be even lower, for example less than 10⁻⁷ mbar.

It is likewise preferred for one or more layers to be coated by means of the OVPD (organic vapour phase deposition) process or with the aid of carrier-gas sublimation, in which the materials are applied at a pressure of between 10⁻⁵ mbar and 1 bar. A special case of this process is the OVJP (organic vapour jet printing) process, in which the materials are applied directly through a nozzle and are thus structured (for example M. S. Arnold et al., Appl. Phys. Lett. 2008, 92, 053301).

It is furthermore preferred for one or more layers to be produced from solution, such as, for example, by spin coating, or by means of any desired printing process, such as, for example, screen printing, flexographic printing, nozzle printing or offset printing, but particularly preferably LITI (light induced thermal imaging, thermal transfer printing) or ink-jet printing. In particular, the emitting layer of the device according to the invention is preferably applied from solution. For this purpose, preference is given to the use of formulations comprising the compounds E, M1 and M2, as described above.

For the production of the electronic device, it is furthermore preferred for one or more layers to be applied from solution and for one or more layers to be applied by a sublimation process.

According to a preferred embodiment, the electronic device according to the invention can be employed in displays, as light source in lighting applications or as light source in medical or cosmetic applications.

### WORKING EXAMPLES

The following working examples serve to illustrate the invention. They should not be interpreted as restrictive.

A) Measurement of the HOMO and LUMO Values for Compounds for Use in the Emitting Layer

The HOMO and LUMO positions and the triplet level of the materials are determined via quantum-chemical calculations. To this end, the “Gaussian-03W” software package (Gaussian Inc.) is used. In order to calculate organic substances without metals, firstly a geometry optimisation is carried out using the “Ground State/Semi-empirical/Default Spin/AM1/Charge 0/Spin Singlet” method. This is followed by an energy calculation on the basis of the optimised geometry. The “TD-SFC/DFT/Default Spin/B3PW91” method with the “6-31G(d)” base set is used here (Charge 0, Spin Singlet). For organometallic compounds, the geometry is optimised via the “Ground State/Hartree-Fock/Default Spin/LanL2 MB/Charge 0/Spin Singlet” method.

The energy calculation is carried out analogously to the organic substances as described above, with the difference that the “LanL2DZ” base set is used for the metal atom and the “6-31G(d)” base set is used for the ligands. The energy calculation gives the HOMO HEh or LUMO LEh in hartree units. The HOMO and LUMO values calibrated with reference to cyclic voltammetry measurements are determined therefrom in electron volts as follows:

HOMO(eV)=((HEh*27.212)−0.9899)/1.1206

LUMO(eV)=((LEh*27.212)−2.0041)/1.385

For the purposes of this application, these values are to be regarded as HOMO and LUMO respectively of the materials. For example, an HOMO of −0.19767 hartrees and an LUMO of −0.04783 hartrees are obtained from the calculation, which corresponds to a calibrated HOMO of −5.68346 eV and a calibrated LUMO of −2.38675 eV.

The following table shows the HOMO and LUMO values determined for the compounds used in the compounds according to the invention in the emitting layer. The structures of the compounds are shown in Table 4. The compounds are known per se for use in OLEDs, and processes for their synthesis are described in the prior art.

TABLE 1
HOMO and LUMO values of the materials

| Material | HOMO (eV) | LUMO (eV) |
|---|---|---|
| NPB | −5.19 | −2.34 |
| M1 | −5.56 | −2.70 |
| D1 | −5.34 | −2.79 |
| StA | −5.05 | −2.56 |
| TPB | −5.29 | −2.74 |
| MA1 | −5.25 | −2.18 |
| MA2 | −5.26 | −2.17 |

B) Production of OLEDs

The results of various OLEDs are presented in the following Examples V1 to V5 and E1 to E3 (see Table 2 for structure of the devices and Table 3 for measurement data obtained for the devices). Examples with letter E and following number denote examples according to the invention, examples with letter V and following number denote comparative examples.

Glass plates coated with structured ITO (indium tin oxide) in a thickness of 50 nm are cleaned by wet methods (dishwasher, detergent Merck Extran). Firstly, these glass plates are treated with a UV ozone plasma, and a 20 nm PEDOT:PSS layer (poly(3,4-ethylenedioxythiophene) poly(styrene-sulfonate), purchased as CLEVIOS™ P VP Al 4083 from Heraeus Clevios Deutschland, applied by spin coating from aqueous solution) is applied for improved processing. The glass plates form the substrates to which the OLEDs are applied.

The OLEDs have in principle the following layer structure: substrate/HTL layer arrangement/emission layer (EML)/electron-transport layer (ETL)/electron-injection layer (EIL) and finally a cathode. The HTL layer arrangement consists of 140 nm of SpA1, 5 nm of HATCN and 20 nm of MA1. The cathode is formed by an aluminium layer with a thickness of 100 nm.

The precise structure of the OLEDs is shown in Table 2. The materials required for the production of the OLEDs are shown in Table 4.

All materials are applied by thermal vapour deposition in a vacuum chamber. The emission layer here always consists of at least one matrix material (host material) and an emitting dopant (emitter), which is adixed with the matrix material or matrix materials in a certain proportion by volume by coevaporation. An expression such as M1:NPB:TPB (93%:5%:2%) here means that the material M1 is present in the layer in a proportion by volume of 93%, NPB is present in the layer in a proportion of 5% and TPB is present in the layer in a proportion of 2%.

The OLEDs are characterised by standard methods. For this purpose, the electroluminescence spectra, the current efficiency (measured in cd/A), the power efficiency (measured in lm/W) and the external quantum efficiency (EQE, measured in percent) as a function of the luminous density, calculated from current/voltage/luminous density characteristic lines (IUL characteristic lines) assuming Lambert emission characteristics, and the lifetime are determined. The electroluminescence spectra are determined at a luminous density of 1000 cd/m², and the CIE 1931 x and y colour coordinates are calculated therefrom. The expression U1000 in Table 3 denotes the voltage necessary for a luminous density of 1000 cd/n2. CE1000 and PE1000 denote the current and power efficiency respectively which are achieved at 1000 cd/rr2. Finally, EQE1000 denotes the external quantum efficiency at an operating luminous density of 1000 cd/m². The lifetime LT is defined as the time after which the luminous density drops from the initial luminous density L0 to a certain proportion L1 on operation at constant current. An expression of L0=6000 cd/m² and L1=70% in Table 3 means that the lifetime indicated in column LT corresponds to the time after which the initial luminous density drops from 6000 cd/m² to 4200 cd/m².

The data of the various OLEDs are summarised in Table 3. Devices V1 to V5 here represent comparative devices, devices E1 to E3 here represent electronic devices in accordance with the present invention.

The data obtained show that significantly better values for voltage, but in particular also efficiency and lifetime, are obtained with emitter compounds (compound D1) whose HOMO position is between those of the two matrix materials than is the case for comparative devices which do not have this feature.

For example, device E1, in which the emitter compound has an HOMO which is between the HOMOs of the two matrix materials, exhibits significantly better values for efficiency and lifetime than device V3, in which the HOMO of the emitter is higher than the HOMO of the two matrix materials. An analogous situation with comparable measurement results exists for device E2 in accordance with the invention compared with device V4.

Furthermore, the examples show that significantly better performance data (in particular quantum efficiency and lifetime) are achieved with devices according to the invention which comprise, as emitter, a compound having 2 to 4 aromatic rings condensed with one another than with devices which comprise, as emitter, a compound having more than four aromatic rings condensed with one another (TBP).

This is shown by a comparison of the data for devices E1 to E3 according to the invention with comparative devices V1, V2 and V5.

TABLE 2
Structure of the OLEDs

| | EML | ETL | EIL |
|---|---|---|---|
| Ex. | Thickness | Thickness | Thickness |
| V1 | M1:NPB:TBP (93%:5%:2%) | ST1:LiQ (50%:50%) | LiQ |
| | 30 nm | 20 nm | 1 nm |
| V2 | M1:MA1:TBP (91%:7%:2%) | ST1:LiQ (50%:50%) | LiQ |
| | 30 nm | 20 nm | 1 nm |
| V3 | M1:NPB:StA (90%:5%:5%) | ST1:LiQ (50%:50%) | LiQ |
| | 30 nm | 20 nm | 1 nm |
| V4 | M1:MA1:StA (90%:5%:5%) | ST1:LiQ (50%:50%) | LiQ |
| | 30 nm | 20 nm | 1 nm |
| V5 | M1:MA2:TBP (91%:7%:2%) | ST1:LiQ (50%:50%) | LiQ |
| | 30 nm | 20 nm | 1 nm |
| E1 | M1:NPB:D1 (90%:5%:5%) | ST1:LiQ (50%:50%) | LiQ |
| | 30 nm | 20 nm | 1 nm |
| E2 | M1:MA1:D1 (90%:5%:5%) | ST1:LiQ (50%:50%) | LiQ |
| | 30 nm | 20 nm | 1 nm |
| E3 | M1:MA2:D1 (90%:7%:3%) | ST1:LiQ (50%:50%) | LiQ |
| | 30 nm | 20 nm | 1 nm |

TABLE 3
Data of the OLEDs

| | U1000 | CE1000 | PE1000 | EQE | CIE x/y at | | L1 | LT |
|---|---|---|---|---|---|---|---|---|
| Ex. | (V) | (cd/A) | (lm/W) | 1000 | 1000 cd/m² | L0 | % | (h) |
| V1 | 4.5 | 9.2 | 4.5 | 6.0% | 0.14/0.21 | 6000 | 70 | 130 |
| | | | | | | cd/m² | | |
| V2 | 4.3 | 10 | 7.2 | 6.7% | 0.14/0.20 | 6000 | 70 | 180 |
| | | | | | | cd/m² | | |
| V3 | 4.8 | 6.7 | 4.4 | 6.0% | 0.15/0.15 | 6000 | 70 | 60 |
| | | | | | | cd/m² | | |
| V4 | 4.4 | 6.9 | 4.9 | 6.1% | 0.14/0.15 | 6000 | 70 | 100 |
| | | | | | | cd/m² | | |
| V5 | 4.4 | 9.9 | 7.1 | 6.9% | 0.14/0.20 | 6000 | 70 | 195 |
| | | | | | | cd/m² | | |
| E1 | 4.5 | 6.2 | 4.3 | 6.4% | 0.15/0.10 | 6000 | 70 | 180 |
| | | | | | | cd/m² | | |
| E2 | 4.3 | 7.7 | 5.6 | 7.9% | 0.14/0.10 | 6000 | 70 | 240 |
| | | | | | | cd/m² | | |
| E3 | 4.4 | 7.6 | 5.4 | 7.8% | 0.14/0.10 | 6000 | 70 | 260 |
| | | | | | | cd/m² | | |

TABLE 4
Structural formulae of the materials used

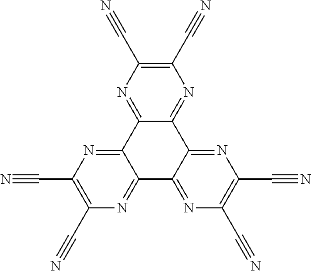 [SMILES: N#Cc1nc2c3nc(C#N)c(C#N)nc3c3nc(C#N)c(C#N)nc3c2nc1C#N]

HATCN

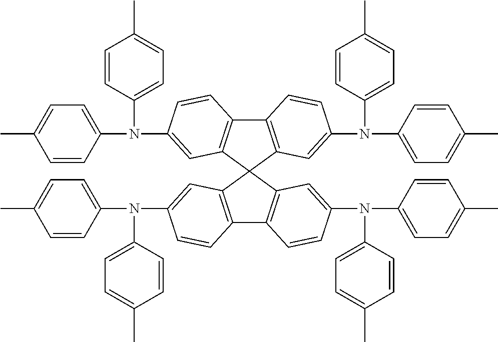

SpA1

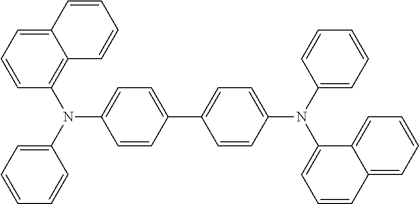 [SMILES: c1ccc(N(c2ccc(-c3ccc(N(c4ccccc4)c4cccc5ccccc45)cc3)cc2)c2cccc3ccccc23)cc1]

NPB

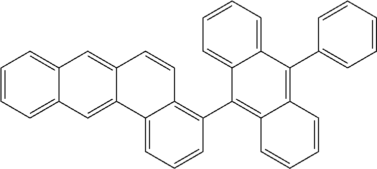 [SMILES: c1ccc(-c2c3ccccc3c(-c3cccc4c3ccc3cc5ccccc5cc34)c3ccccc23)cc1]

M1

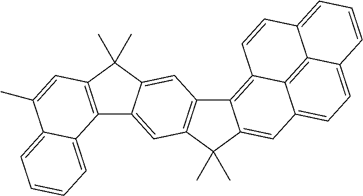 [SMILES: Cc1cc2c(c3ccccc13)-c1cc3c(cc1C2(C)C)-c1c(cc2ccc4cccc5ccc1c2c45)C3(C)C]

D1

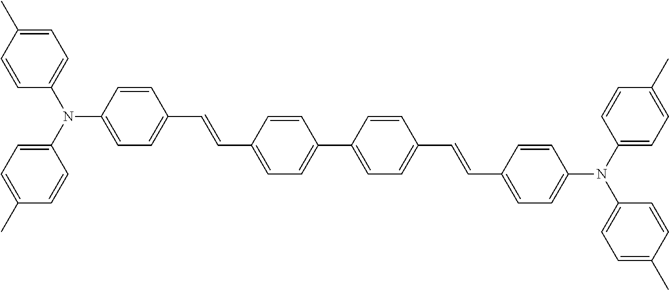 [SMILES: Cc1ccc(N(c2ccc(C)cc2)c2ccc(/C=C/c3ccc(-c4ccc(/C=C/c5ccc(N(c6ccc(C)cc6)c6ccc(C)cc6)cc5)cc4)cc3)cc2)cc1]

StA

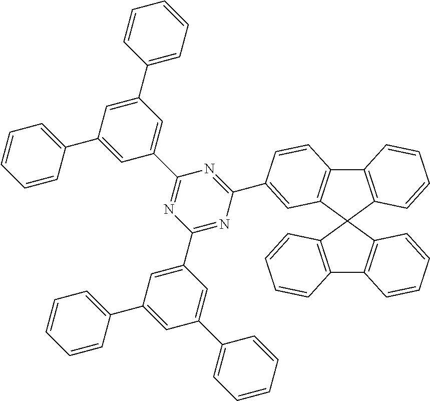 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

ST1

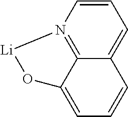

LiQ

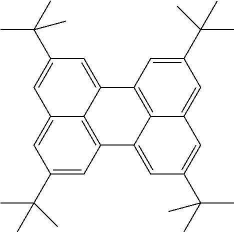 [SMILES: CC(C)(C)c1cc2cc(C(C)(C)C)cc3c4cc(C(C)(C)C)cc5cc(C(C)(C)C)cc(c(c1)c23)c54]

TBP

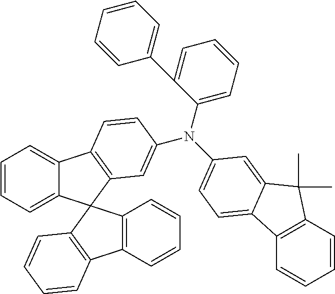 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

MA1

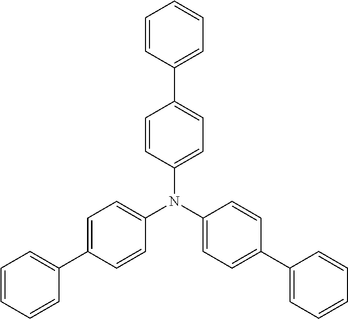 [SMILES: c1ccc(-c2ccc(N(c3ccc(-c4ccccc4)cc3)c3ccc(-c4ccccc4)cc3)cc2)cc1]

MA2

1-15. (canceled)

16. An electronic device comprising an anode, a cathode, and at least one emitting layer, wherein:
the emitting layer comprises at least one emitter compound E, at least one matrix material M1, and at least one matrix material M2;
the emitter compound E is selected from compounds comprising at least one condensed aryl group consisting of 2 to 4 aromatic rings condensed with one another;
the matrix material M2 is selected from compounds comprising at least one anthracene unit; and
the following applies to the HOMOs of compounds E, M1, and M2:
HOMO(M1)>HOMO(E)>HOMO(M2).

17. The electronic device of claim 16, wherein the emitter compound E is a fluorescent compound.

18. The electronic device of claim 16, wherein the emitter compound E contains no arylamino group.

19. The electronic device of claim 16, wherein the emitter compound E contains at least one group selected from the group consisting of pyrenyl groups, anthracenyl groups, fluorenyl groups, and indenofluorenyl groups.

20. The electronic device of claim 16, wherein the emitter compound E is a compound of formula (I): 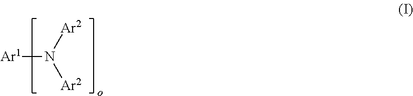
wherein
Ar¹ is an aromatic or heteroaromatic ring system having 10 to 40 aromatic ring atoms and comprising at least one condensed aryl or heteroaryl group consisting of 2 to 4 aromatic rings condensed with one another, wherein the aromatic or heteroaromatic ring system is optionally substituted by one or more radicals R¹;
Ar² is an aromatic or heteroaromatic ring system having 6 to 40 aromatic ring atoms, optionally substituted by one or more radicals R¹;
R¹ is on each occurrence, identically or differently, H, D, F, C(═O)R², CN, Si(R²)₃, N(R²)₂, P(═O)(R²)₂, S(═O)R², S(═O)₂R², a straight-chain alkyl or alkoxy group having 1 to 20 C atoms or a branched or cyclic alkyl or alkoxy group having 3 to 20 C atoms or an alkenyl or alkynyl group having 2 to 20 C atoms, wherein said groups are optionally substituted by one or more radicals R², and wherein one or more CH₂ groups in said groups are optionally replaced by —R²C═CR²—, —C≡C—, Si(R²)₂, C═O, C═S, C═NR², —C(═O)O—, —C(═O)NR²—, NR², P(═O)(R²), —O—, —S—, SO, or SO₂, and wherein one or more H atoms in said groups is optionally replaced by D, F, or CN, an aromatic or heteroaromatic ring system having 5 to 30 aromatic ring atoms, optionally substituted by one or more radicals R², or an aryloxy or heteroaryloxy group having 5 to 30 aromatic ring atoms, optionally substituted by one or more radicals R², and wherein two or more radicals R¹ are optionally linked to one another so as to define a ring;
R² is on each occurrence, identically or differently, H, D, F, or an aliphatic, aromatic or heteroaromatic organic radical having 1 to 20 C atoms, wherein one or more H atoms are optionally replaced by D or F; and wherein two or more substituents R² are optionally linked to one another so as to define a ring; and
o is 0, 1, 2, 3, or 4.

21. The electronic device of claim 20, wherein o is 0, 1, or 2.

22. The electronic device of claim 20, wherein Ar¹ is selected from the following groups: 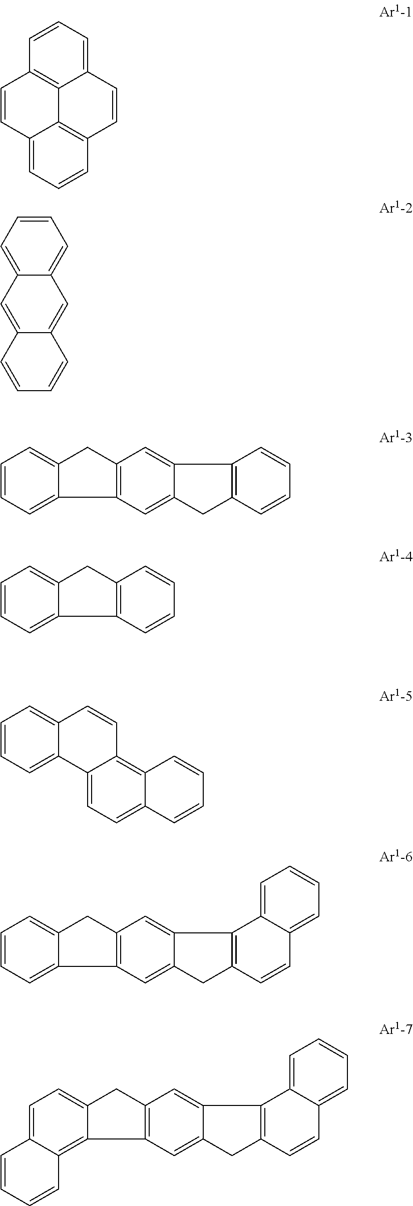
wherein
the groups are optionally substituted at all free positions by one or more radicals R¹, and
the groups of formulae Ar¹-3 and Ar¹-4 must comprise at least one additional condensed-on aromatic ring which is condensed onto one of the six-membered rings.

23. The electronic device of claim 22, wherein the groups of formula Ar¹-3 and Ar¹-4 comprise two or three additional condensed-on aromatic rings, which can be condensed onto a single six-membered ring or onto a plurality of different six-membered rings.

24. The electronic device of claim 16, wherein M1 is a monotriarylamino compound.

25. The electronic device of claim 16, wherein E, M1, and M2 are different.

26. The electronic device of claim 16, wherein the LUMO of M2 has a lower value than the LUMO of M1 and the LUMO of E.

27. The electronic device of claim 16, wherein M1 is present in the emitting layer in a proportion of 1 to 90% by volume.

28. The electronic device of claim 16, wherein the electronic device is selected from the group consisting of organic light-emitting transistors, organic solar cells, organic optical detectors, organic photoreceptors, organic field-quench devices, organic light-emitting electrochemical cells, organic laser diodes, and organic electroluminescent devices.

29. The electronic device of claim 16, wherein the electronic device is an organic electroluminescent device and comprises at least one further emitting layer.

30. A display, light source in lighting applications, or a light source in medical or cosmetic applications comprising the electronic device of claim 16.
